(19) United States
(12) Patent Application Publication
(10) Pub. No.: US 2025/0293801 A1
(43) Pub. Date: Sep. 18, 2025

(54) METHOD, SYSTEM, AND APPARATUS FOR MULTIPLEXED TRANSMISSION OF DIFFERENT TRANSMISSION TYPES

(71) Applicant: Huawei Technologies Co., Ltd., Shenzhen (CN)

(72) Inventors: Huazi Zhang, Hangzhou (CN); Yan Chen, Kanata (CA); Xiaoyan Bi, Shanghai (CN); Jianglei Ma, Ottawa (CA); Wen Tong, Ottawa (CA)

(21) Appl. No.: 19/208,215

(22) Filed: May 14, 2025

Related U.S. Application Data
(63) Continuation of application No. PCT/CN2022/131972, filed on Nov. 15, 2022.

(51) Int. Cl. H04L 1/00

(52) U.S. Cl. CPC H04L 1/0042; H04L 1/0057; H04L 1/0071

(57) ABSTRACT

Methods and apparatuses for preemption-coding are described. During a scheduled transmission of a first set of data belonging to a first incumbent transmission type to an intended receiver node, a second set of data belonging to a second preemptive transmission type is received. At least one bit of the first set of data and at least one bit of the second set of data are multiplexed to generate at least one multiplexed code block containing information from both the first and second sets of data. The multiplexed code block is transmitted to one or more intended recipients.

### CROSS-REFERENCE TO RELATED APPLICATION

This application is a continuation of International Application No. PCT/CN2022/131972, filed on Nov. 15, 2022, the disclosure of which is hereby incorporated by reference in its entirety.

### TECHNICAL FIELD

The present disclosure relates to methods and apparatuses for wireless communications of different transmission types, in particular wireless communications in which a preemptive transmission type preempts transmission of an incumbent transmission type.

### BACKGROUND

Wireless communications can involve different transmission types that may have different requirements. Ultra-reliable low latency communications (URLLC), enhanced mobile broadband (eMBB), massive machine type communications (mMTC) are transmission types, defined for 5G wireless communications, that have different requirements for latency, reliability, connectivity, etc. For example, URLLC is intended to be used for critical transmissions (e.g., in autonomous driving applications, emergency services, etc.) that have stringent latency and reliability requirements.

In some examples, it may be desirable for one type of transmission (e.g., a higher priority transmission type, such as a URLLC transmission) to be permitted to preempt another type of transmission (e.g., a lower priority transmission type, such as an eMBB transmission). However, such preemption can cause significant performance degradation of the preempted transmission type.

Therefore, it would be useful to provide techniques that enable coexistence of different transmission types, that avoid or reduce performance degradation caused by preemption.

### SUMMARY

In various examples, the present disclosure describes methods and apparatuses for wireless communications using multiplexed transmissions (also referred to as multiplexed services). In particular, an incumbent (i.e., a currently scheduled or currently ongoing) transmission type (e.g., eMBB) is multiplexed with a preemptive transmission type (e.g., URLLC or mMTC) in a multiplexed transmission. This provides the technical advantage that the incumbent data may not be catastrophically impacted by the preemptive transmission, thus helping to avoid or reduce the need for retransmissions of the incumbent data.

Additionally, examples of the present disclosure enable the preemptive transmission type to be transmitted with low latency, which may be important for certain latency-critical transmission types. As well, in some examples there may be improved coding gain for the preemptive data, due to the increased code length when multiplexed with the incumbent data.

In an example aspect, the present disclosure describes a method at a transmitter node, the method including: during or before a scheduled transmission of a first set of data belonging to a first (e.g., incumbent) transmission type to an intended receiver node, obtaining a second set of data belonging to a second (e.g., preemptive) transmission type to be transmitted to the same or different intended receiver node; multiplexing at least one bit of the first set of data and at least one bit of the second set of data to generate at least one multiplexed code block containing information from both the first and second sets of data; and outputting (e.g., transmitting) the at least one multiplexed code block.

In an example of the preceding example aspect of the method, the first and second sets of data may be transmitted to the same intended receiver node, and multiplexing the at least one bit of the first set of data and the at least one bit of the second set of data may include: jointly encoding the at least one bit of the first set of data and the at least one bit of the second set of data into a jointly encoded codeword.

In an example of a preceding example aspect of the method, the first and second sets of data may be transmitted to the same intended receiver node, and multiplexing the at least one bit of the first set of data and the at least one bit of the second set of data may include: scrambling the at least one bit of the first set of data using a bit mask generated from the at least one bit of the second set of data.

In an example of a preceding example aspect of the method, the first and second sets of data may be transmitted to the same intended receiver node, and multiplexing the at least one bit of the first set of data and the at least one bit of the second set of data may include: interleaving the at least one bit of the first set of data using a permutation sequence generated from the at least one bit of the second set of data.

In an example of any of the preceding example aspects of the method, there may be a plurality of multiplexed code blocks, and one or more bits of the second set of data may be multiplexed in each of the plurality of multiplexed code blocks.

In an example of a preceding example aspect of the method, the first and second sets of data may be transmitted to different intended receiver nodes, and multiplexing the at least one bit of the first set of data and the at least one bit of the second set of data may include: performing multi-level coding between the at least one bit of the first set of data and the at least one bit of the second set of data to obtain a multi-level coded symbol; and the multiplexed code block containing the multi-level coded symbol may be transmitted to the different intended receiver nodes.

In an example of the preceding example aspect of the method, performing multi-level coding may include: mapping the at least one bit of the first set of data and the at least one bit of the second set of data to respective different levels; for each level, encoding one or more bits carried on the level to a respective codeword; and jointly mapping at least one code bit selected from each codeword to the multi-level coded symbol.

In an example of a preceding example aspect of the method, the first and second sets of data may be transmitted to different intended receiver nodes, and multiplexing the at least one bit of the first set of data and the at least one bit of the second set of data may include: performing masked repetition coding between the at least one bit of the first set of data and the at least one bit of the second set of data to obtain a masked repetition coded symbol; and the multiplexed code block containing the masked repetition coded symbol may be transmitted to the different intended receiver nodes.

In an example of the preceding example aspect of the method, performing masked repetition coding may include: generating a first codeword from the at least one bit of the first set of data, two or more copies of the first codeword being generated; generating a second codeword from the at least one bit of the second set of data; and masking the second codeword onto at least one copy of the first codeword, the masked repetition coded symbol being generated from the at least one masked copy.

In an example of any of the preceding example aspects of the method, the method may include: after all bits of the second set of data have been transmitted, resuming the scheduled transmission of the first set of data.

In an example of any of the preceding example aspects of the method, the method may include: transmitting control information to at least one intended receiver node, the control information including information for decoding the at least one multiplexed code block.

In an example of the preceding example aspect of the method, an updated transport block size may be computed for the multiplexed code block and the updated transport block size may be included in the transmitted control information.

In an example of any of the preceding example aspects of the method, the method may include: mapping symbols of the at least one multiplexed code block to non-consecutive resource elements; and transmitting the at least one multiplexed code block after the mapping.

In an example of any of the preceding example aspects of the method, the first set of data belonging to the first incumbent transmission type may be enhanced mobile broadband (eMBB) data, and the second set of data belonging to the second preemptive transmission type may be higher priority small packet data.

In an example of the preceding example aspect of the method, the higher priority small packet data may be ultra-reliable low latency communications (URLLC) data or massive machine type communications (mMTC) data.

In another example aspect, the present disclosure describes a method at a receiver node, the method including: receiving at least one multiplexed code block generated from multiplexing at least one bit of a first set of data and at least one bit of a second set of data to contain information from both the first and second sets of data, the first set of data belonging to a first transmission type and scheduled for the receiver node, and the second set of data belonging to a second transmission type and intended for the same receiver node or a different receiver node; and decoding at least the information from the first set of data.

In another example aspect, the present disclosure describes a method at a receiver node, the method including: receiving at least one multiplexed code block generated from multiplexing at least one bit of a first set of data and at least one bit of a second set of data to contain information from both the first and second sets of data, the first set of data belonging to a first transmission type and scheduled for the same receiver node or a different receiver node, and the second set of data belonging to a second transmission type and intended for the same receiver node; and decoding at least the information from the second set of data.

In another example aspect, the present disclosure describes an apparatus including a processing unit configured to cause the apparatus to perform any of the preceding example aspects of the method.

In another example aspect, the present disclosure describes a non-transitory computer readable medium having machine-executable instructions stored thereon, wherein the instructions, when executed by a processing unit of an apparatus, cause the apparatus to perform any of the preceding example aspects of the method.

In another example aspect, the present disclosure describes a system comprising a transmitter node and a receiver node. The transmitter node is configured to transmit at least one multiplexed code block generated from multiplexing at least one bit of a first set of data and at least one bit of a second set of data to contain information from both the first and second sets of data, the first set of data belonging to a first transmission type and scheduled for an intended receiver node, and the second set of data belonging to a second transmission type and intended for the same receiver node or a different receiver node. The receiver node is configured to receive the at least one multiplexed code block, and decode at least one of the information from the first set of data or the information from the second set of data.

### BRIEF DESCRIPTION OF THE DRAWINGS

Reference will now be made, by way of example, to the accompanying drawings which show example embodiments of the present application, and in which:

FIG. 1 is a schematic diagram illustrating an example wireless communication system suitable for implementing examples described herein;

FIG. 2 is a block diagram illustrating an example apparatus suitable for implementing examples described herein;

FIG. 3 is a schematic diagram illustrating an example existing coexistence scheme;

FIG. 4 is a schematic diagram illustrating an example of a preemption-coding scheme using combined-data coding, in accordance with examples of the present disclosure;

FIGS. 5A-5C are schematic diagrams illustrating examples of combined-data coding implemented at a transmitter node, in accordance with examples of the present disclosure;

FIGS. 5D and 5E illustrate examples of how a code block may be affected by combined-data coding, in accordance with examples of the present disclosure;

FIGS. 6A and 6B are schematic diagrams illustrating examples of preemption-coding using multi-level coding, in accordance with examples of the present disclosure;

FIGS. 7A-7C are schematic diagrams illustrating examples of multi-stage decoding, in accordance with examples of the present disclosure;

FIG. 8A is a schematic diagram illustrating an example of masked repetition coding based preemption-coding, in accordance with examples of the present disclosure;

FIG. 8B is a schematic diagram illustrating an example of demasking and decoding, in accordance with examples of the present disclosure;

FIG. 9 is a schematic diagram illustrating an example of non-consecutive mapping of symbols to resource elements, in accordance with examples of the present disclosure;

FIG. 10 is a flowchart illustrating an example method for preemption-coding, in accordance with examples of the present disclosure; and

FIGS. 11A-11C are flowcharts illustrating example implementations of the method of FIG. 10, in accordance with examples of the present disclosure.

Similar reference numerals may have been used in different figures to denote similar components.

### DETAILED DESCRIPTION

To assist in understanding the present disclosure, an example wireless communication system is first described.

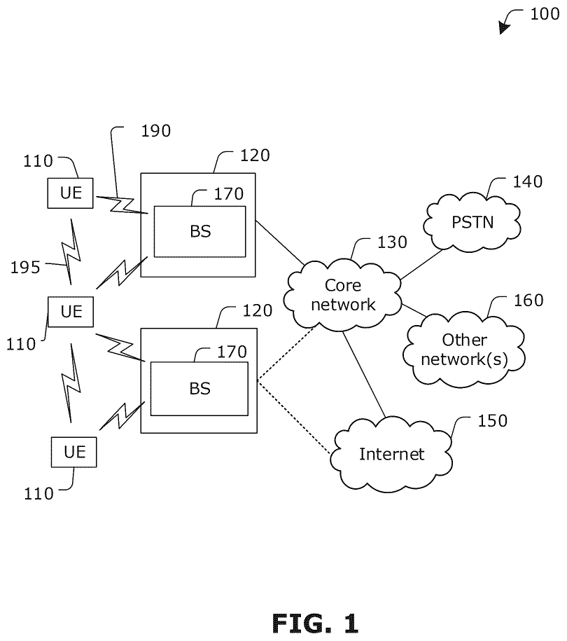

FIG. 1 illustrates an example wireless communication system 100 (also referred to as a wireless system 100) in which embodiments of the present disclosure could be implemented. In general, the wireless system 100 enables multiple wireless or wired elements to communicate data and other content. The wireless system 100 may enable content (e.g., voice, data, video, text, etc.) to be communicated (e.g., via broadcast, narrowcast, user device to user device, etc.) among entities of the system 100. The wireless system 100 may operate by sharing resources such as bandwidth. The wireless system 100 may be suitable for wireless communications using 5G technology and/or later generation wireless technology. In some examples, the wireless system 100 may also accommodate some legacy wireless technology (e.g., 3G or 4G wireless technology).

In the example shown, the wireless system 100 includes user equipment (UEs) 110, radio access networks (RANs) 120, a core network 130, a public switched telephone network (PSTN) 140, the internet 150, and other networks 160. In some examples, one or more of the networks may be omitted or replaced by a different type of network. Other networks may be included in the wireless system 100. Although certain numbers of these components or elements are shown in FIG. 1, any reasonable number of these components or elements may be included in the wireless system 100.

The UEs 110 are configured to operate, communicate, or both, in the wireless system 100. For example, the UEs 110 may be configured to transmit, receive, or both via wireless or wired communication channels. The term “UE” may be used to refer to any suitable end user device for wireless operation and may include such devices (or may be referred to) as a wireless transmit/receive unit (WTRU), a mobile station, a mobile relay, a fixed or mobile subscriber unit, a cellular telephone, a station (STA), a machine type communication (MTC) device, a personal digital assistant (PDA), a smartphone, a laptop, a computer, a tablet, a wireless sensor, an internet of things (IoT) device, a network-enabled vehicle, or a consumer electronics device, among other possibilities. In some examples, the term electronic device (ED) may be used instead of UE. In general, it should be understood that the use of the term UE in the present disclosure does not necessarily limit the present disclosure to any specific wireless technology.

In FIG. 1, the RANs 120 include base stations (BSs) 170. Although FIG. 1 shows each RAN 120 including a single respective BS 170, it should be understood that any given RAN 120 may include more than one BS 170, and any given RAN 120 may also include base station controller(s) (BSC), radio network controller(s) (RNC), relay nodes, elements, and/or devices. Each BS 170 is configured to wirelessly interface with one or more of the UEs 110 to enable access to any other BS 170, the core network 130, the PSTN 140, the internet 150, and/or the other networks 160. For example, the BSs 170 may also be referred to as (or include) a base transceiver station (BTS), a radio base station, a Node-B (NodeB), an evolved NodeB (eNodeB or eNB), a Home eNodeB, a gNodeB (gNB) (sometimes called a next-generation Node B), a transmission point (TP), a transmission and reception point (TRP), a site controller, an access point (AP), or a wireless router, among other possibilities. Future generation BSs 170 may be referred to using other terms. In some examples, the term TRP may be used to encompass a BS 170 or any other node that may serve to transmit and receive communications. Thus, although the present disclosure makes references to BSs 170, it should be understood that this is not intended to be limiting. Any UE 110 may be alternatively or additionally configured to interface, access, or communicate with any other BS 170, the internet 150, the core network 130, the PSTN 140, the other networks 160, or any combination of the preceding. In some examples, a BS 170 may access the core network 130 via the internet 150.

The UEs 110 and BSs 170 are examples of communication equipment that can be used to implement some or all of the functionality and/or embodiments described herein. Any BS 170 may be a single element, as shown, or multiple elements, distributed in the corresponding RAN 120, or otherwise. Each BS 170 transmits and/or receives wireless signals within a particular geographic region or area, sometimes referred to as a “cell” or “coverage area”. A cell may be further divided into cell sectors, and a BS 170 may, for example, employ multiple transceivers to provide service to multiple sectors. In some embodiments there may be established pico or femto cells where the radio access technology supports such. A macro cell may encompass one or more smaller cells. The number of RANs 120 shown is exemplary only. Any number of RANs may be contemplated when devising the wireless system 100.

The BSs 170 communicate with one or more of the UEs 110 over one or more uplink (UL)/downlink (DL) wireless interfaces 190 (e.g., via radio frequency (RF), microwave, infrared, etc.). The UL/DL interface 190 may also be referred to as a UL/DL connection, UE-BS link/connection/interface, or UE-network link/connection/interface, for example. The UEs 110 may also communicate directly with one another (i.e., without involving the BS 170) via one or more sidelink (SL) wireless interfaces 195. The SL interface 195 may also be referred to as a SL connection, UE-to-UE link/connection/interface, vehicle-to-vehicle (V2V) link/connection/interface, vehicle-to-everything (V2X) link/connection/interface, vehicle-to-infrastructure (V2I) link/connection/interface, vehicle-to-pedestrian (V2P) link/connection/interface, device-to-device (D2D) link/connection/interface, or simply as SL, for example. The wireless interfaces 190, 195 may utilize any suitable radio access technology. For example, the wireless system 100 may implement one or more channel access methods, such as code division multiple access (CDMA), time division multiple access (TDMA), frequency division multiple access (FDMA), orthogonal FDMA (OFDMA), or single-carrier FDMA (SC-FDMA) for wireless communications.

The RANs 120 are in communication with the core network 130 to provide the UEs 110 with various services such as voice, data, and other services. The RANs 120 and/or the core network 130 may be in direct or indirect communication with one or more other RANs (not shown), which may or may not be directly served by core network 130, and may or may not employ the same radio access technology. The core network 130 may also serve as a gateway access between (i) the RANs 120 or UEs 110 or both, and (ii) other networks (such as the PSTN 140, the internet 150, and the other networks 160). In addition, some or all of the UEs 110 may include functionality for communicating with different wireless networks over different wireless links using different wireless technologies and/or protocols. Instead of wireless communication (or in addition thereto), the UEs 110 may communicate via wired communication channels to a service provider or switch (not shown), and to the internet 150. PSTN 140 may include circuit switched telephone networks for providing plain old telephone service (POTS). The internet 150 may include a network of computers and subnets (intranets) or both, and incorporate protocols, such as Internet Protocol (IP), Transmission Control Protocol (TCP), User Datagram Protocol (UDP). The UEs 110 may be multimode devices capable of operation according to multiple radio access technologies, and incorporate multiple transceivers necessary to support such.

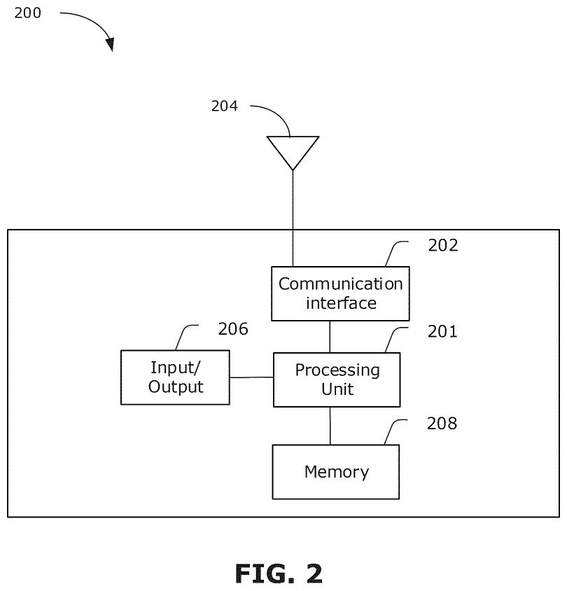

FIG. 2 illustrates an example apparatus 200 that may implement examples disclosed herein. FIG. 2 illustrates a possible embodiment for the UE 110 or the BS 170, and is not intended to be limiting.

As shown in FIG. 2, an example apparatus 200 (e.g., an example embodiment of the UE 110 or BS 170) includes at least one processing unit 201. The processing unit 201 implements various processing operations of the apparatus 200. For example, the processing unit 201 could perform signal coding, data processing, power control, input/output processing, or any other functionality of the apparatus 200. The processing unit 201 may also be configured to implement some or all of the functionality and/or embodiments described in more detail herein. Each processing unit 201 includes any suitable processing or computing device configured to perform one or more operations. Each processing unit 201 could, for example, include a microprocessor, microcontroller, digital signal processor, field programmable gate array, or application specific integrated circuit.

The apparatus 200 includes at least one communication interface 202 for wired and/or wireless communications. One or multiple communication interfaces 202 could be used in the apparatus 200. Each communication interface 202 includes any suitable structure for generating signals for wireless or wired transmission and/or processing signals received wirelessly or by wire. Although shown as a single functional unit, the communication interface 202 could also be implemented using at least one transmitter interface and at least one separate receiver interface. In some examples, one or more transmitters and one or more receivers may be implemented by the communication interface 202.

The apparatus 200 includes one or more antennas 204 for wireless communications. Each antenna 204 includes any suitable structure for transmitting and/or receiving wireless signals. In some examples, the apparatus 200 may include multiple antennas 204 to support multiple-input multiple-output (MIMO) communications. There may be multiple antennas 204 that together form an antenna array, which may be used for beamforming and beam steering operations. In some examples, there may be one or more antennas 204 used for transmitting signals and separate one or more antennas 204 used for receiving signals.

The apparatus 200 further includes one or more input/output devices 206 or input/output interfaces (such as a wired interface to the internet 150). The input/output device(s) 206 permit interaction with a user or other devices in the wireless system 100. Each input/output device 206 includes any suitable structure for providing information to or receiving information from a user, such as a speaker, microphone, keypad, keyboard, display, or touchscreen, including network interface communications.

In addition, the apparatus 200 includes at least one memory 208. The memory 208 stores instructions and data used, generated, or collected by the apparatus 200. For example, the memory 208 could store software instructions or modules configured to implement some or all of the functionality and/or embodiments described herein and that are executed by the processing unit(s) 201. Each memory 208 includes any suitable volatile and/or non-volatile storage and retrieval device(s). Any suitable type of non-transitory memory may be used, such as random access memory (RAM), read only memory (ROM), hard disk, optical disc, subscriber identity module (SIM) card, memory stick, secure digital (SD) memory card, and the like.

A wireless system (e.g., the wireless system 100 of FIG. 1) may support different transmission types, also referred to as transmission services (or simply services). For example, ultra-reliable low latency communications (URLLC), enhanced mobile broadband (eMBB), massive machine type communications (mMTC) are transmission types, defined for 5G wireless communications, that have different requirements for latency, reliability, connectivity, etc. In particular, URLLC is intended to be used for high-priority transmissions, such as those in critical applications including public safety, telemedicine, emergency services, autonomous driving, and industrial automation, among others. URLLC services have stringent latency and reliability requirements (e.g., less than 1 ms latency and over 99% reliability).

In an example scenario, URLLC and eMBB transmissions may coexist in DL or UL communications. For example, transmissions from a BS 170 to a UE 110 (or vice versa) may be mostly eMBB transmissions. However, a high-priority URLLC transmission may occasionally arrive and need to be immediately transmitted (e.g., with less than 1 ms latency) from the BS 170. In another example, a UE 110 may be a cluster head of a cluster of MTC devices and the UE 110 may need to send mMTC transmissions on top of existing eMBB transmissions. It should be understood that these examples are not intended to be limiting. The present disclosure may be applicable to DL, UL or SL transmissions, and may include transmissions with one intended recipient or multiple intended recipients. Accordingly, the present disclosure will make reference to transmissions from a transmitter node (which may be a BS 170 for a DL transmissions, or a UE 110 for an UL or SL transmission) and receipt of the transmissions at one or more receiver nodes (which may be a BS 170 for an UL transmission, or a UE 110 for a DL or SL transmission).

Various service coexistence schemes have been developed to enable different transmission types to be communicated according to their respective latency requirements. For example, URLLC transmissions can be quite small (e.g., a few bits to a few bytes in length) compared to typical eMBB packets. This may enable URLLC transmissions to preempt (that is, take over) some of the resources allocated to eMBB transmission. In another example, mMTC transmissions are typically quite small compared to eMBB transmissions but are generally not time-critical. Because transmitting a very small packet by itself is spectrally inefficient, a mMTC packet may instead be delayed until it can be transmitted together with a larger eMBB packet.

A drawback of existing coexistence schemes that allow for preemption is that the performance of the preempted transmission can be significantly degraded.

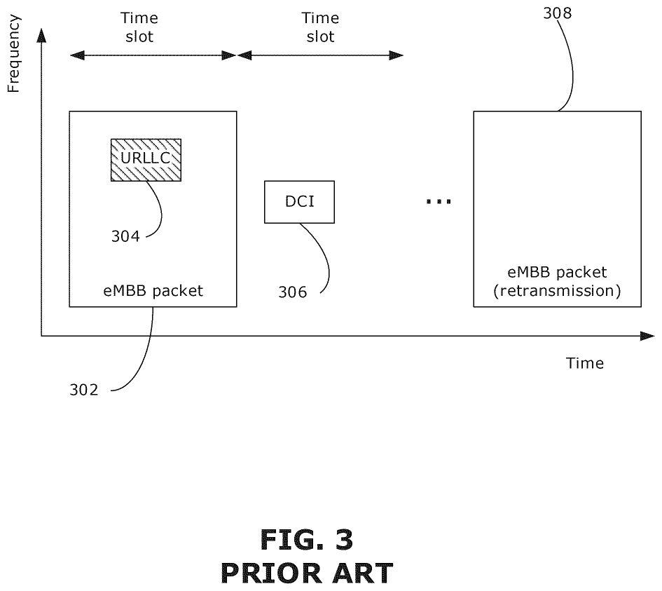

FIG. 3 is a schematic diagram illustrating an example of how a URLLC transmission may preempt an eMBB transmission, according to some existing coexistence schemes.

Consider the case in which a transmitter node uses certain scheduled resources to send an eMBB packet 302 in a current timeslot to a receiver node. The eMBB transmission is thus a currently scheduled, ongoing transmission. This means that the receiver node may have received scheduling signaling indicating the incoming eMBB transmission. However, a URLLC packet arrives at the physical layer and, in accordance with the coexistence scheme (which prioritizes URLLC transmissions), the transmitter node immediately allocates some resource position (OFDM symbols) in the current timeslot for the URLLC packet 304. In other words, the URLLC packet 304 has preempted (i.e., replaced) some of the symbols of the eMBB packet 302. Typically, the URLLC packet 304 only occupies part of the resource slot because URLLC packets are usually very small. The receiver node thus receives the eMBB packet 302 with some symbols preempted by the URLLC packet 304. It should be noted that though the receiver node is the intended recipient of the eMBB packet 302, the same receiver node may or may not be the intended recipient of the URLLC packet 304.

It should be noted the URLLC transmission preempts the scheduled eMBB transmission without having sent any scheduling signaling to the receiver node beforehand. At the beginning of the next timeslot, a preemption indicator (e.g., sent in a control signal such as a downlink control information (DCI) 306) is transmitted to the receiver node over the control channel to indicate the preempted resource position. In this way, the receiver knows which symbols belong to the URLLC packet 304 and which belong to the eMBB packet 302. The receiver node, when attempting to decode the eMBB packet 302, thus flushes (i.e., discards) the soft-decision bits (usually expressed as log-likelihood ratios, LLRs) belonging to the URLLC packet 304. Conceptually this may be equivalent to treating the eMBB packet 302 as if it were punctured for rate-matching. However, proper puncturing requires careful design of the puncturing pattern so that the punctured packet can be recoverable. In the case where the URLLC packet 302 preempts a portion of the eMBB packet 302, the symbols that are preempted may be selected arbitrarily, and typically the eMBB packet 302 would be significantly impaired and a retransmission 308 of the eMBB packet will be required.

Thus, existing coexistence schemes enable URLLC packets to preempt eMBB packets in a way that ensures the URLLC packet is received with reduced latency, but at the expense of significant performance degradation of eMBB transmissions. Although the above discussion describes preemption of eMBB transmission by URLLC packets, in general such drawbacks may occur in any coexistence scheme in which a first incumbent transmission (e.g., lower priority transmission) can be preempted by a second transmission (e.g., higher priority transmission). Thus, the problems addressed by the present disclosure are not necessarily limited to those caused by a URLLC transmission preempting an eMBB transmission.

Another drawback of existing coexistence schemes is that, when the preempting packet (e.g., the URLLC packet) is very small (e.g., containing fewer than 10 bits), the coding gain is relatively small even after the code rate is set to be very low. According to coding theory, coding gain is mostly a result of long code length, which may be limited in existing coexistence schemes. Accordingly, for such small packets, their error correction performance can be further improved.

The present disclosure describes coexistence schemes that may help to avoid or mitigate at least some of the drawbacks discussed above.

In examples of the present disclosure, various preemption-coding schemes are described. Preemption-coding may also be referred to as multi-service multiplexing (i.e., multiplexing of different transmission types corresponding to different services). In the disclosed preemption-coding schemes, the information of both a first incumbent transmission (e.g., lower priority transmission) and a second transmission (e.g., higher priority transmission) can be preserved and recoverable, unlike existing preemption schemes that effectively cause the second transmission to puncture the first transmission. Preemption-coding may be performed in various ways, such as joint coding of multiple payloads, scrambling or permutation of one transmission to carry data of an additional transmission, multi-level coding or masked repetition coding. These techniques will be described in detail further below.

The present disclosure also describes example resource mapping schemes. In existing preemption schemes, symbols of a second packet (e.g., a higher priority packet such as a URLLC packet) are mapped to consecutive physical resource blocks (and thus preempts consecutive symbols) of an incumbent first packet (e.g., a lower priority packet such as an eMBB packet); in contrast, the presently-disclosed example resource mapping schemes allow for the symbols of the second packet to instead be mapped to spaced-apart resource elements. Some techniques for this mapping will be described further below. Since a timeslot may contain many code blocks (CBs) of the first packet, by spreading the symbols of the second packet in this way, each CB of the first packet may be interfered with only slightly and thus there may be lower negative impact on the success of decoding the CBs.

Example preemption-coding schemes using joint coding, scrambling, or permutation are first described. Such preemption-coding schemes enable the data of a second packet (e.g., a higher priority packet such as a URLLC packet) to be explicitly or implicitly embedded into the data of an incumbent first packet (e.g., a lower priority packet such as an eMBB packet). In the present disclosure, preemption-coding schemes that embed data of a second packet into the data of an incumbent first packet may be referred to as combined-data coding (to distinguish from other types of preemption coding such as multi-level coding and masked repetition coding, discussed further below). Preemption-coding schemes using combined-data coding may, for example, use joint coding, scrambling, or permutation as discussed further below. Unlike existing preemption schemes, in combined-data coding schemes disclosed herein the symbols of the first packet are not removed or replaced by the second packet. Instead, one or more CBs of the first packet are replaced with corresponding one or more combined-data-coded CBs, where the combined-data-coded CB(s) is (are) encoded with the payload data of both the first and second packets. Then, when the packet including the combined-data-coded CB(s) is received at the receiver node, the receiver node can jointly decode the received packet without having to flush a portion of the received signals.

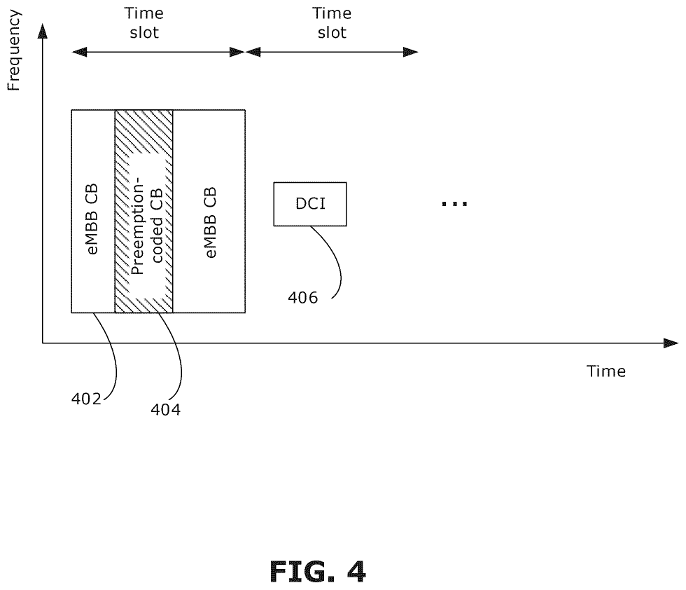

FIG. 4 is a schematic diagram illustrating an example of an example preemption-coding scheme using combined-data coding.

FIG. 4 illustrates a scenario similar to that of FIG. 3, in which a higher priority second data (e.g., URLLC data) arrives during transmission of a lower priority data (e.g., eMBB data). The lower priority data is a currently scheduled, ongoing incumbent transmission (e.g., scheduling signaling may have been sent to the receiver node to indicate this transmission). The higher priority data arrives and is to be transmitted without being first scheduled with the receiver node; thus, the higher priority data preempts the lower priority transmission. However, using an example of the disclosed combined-data coding scheme, portions of the lower priority data are not entirely displaced by the higher priority second data. Instead of removing the symbols of the incumbent eMBB CBs 402, one or more of the eMBB CBs 402 are replaced with corresponding one or more combined-data-coded CBs 404. The combined-data-coded CBs 404 are generated by the transmitter node using a combination of both the incumbent lower priority data as well as the newly arrived higher priority data (e.g., using joint coding, scrambling or permutation operations). When all of the higher priority data has been coded (together with the incumbent lower priority data) into the combined-data-coded CB(s) 404, the transmitter node can resume transmission of the eMBB CBs 402 (which contain only the lower priority eMBB data).

At the beginning of the next timeslot, a preemption-coding indicator (e.g., sent in a control signal such as a DCI 406) is transmitted to the receiver node over the control channel to indicate the position of the preemption-coded CB(s) (i.e., the combined-data-coded CB(s) 404), as well as additional information (e.g., type of preemption-coding performed by the transmitter node, updated TB size, etc.) required by the receiver node to decode the combined-data-coded CB(s) 404. The receiver node is thus able to decode the combined-data-coded CB(s) 404 to recover both the incumbent lower priority data (e.g., eMBB data) as well as the higher priority data (e.g., URLLC data). It should be noted that, while a DCI 406 is shown in FIG. 4, any suitable control signaling may be used. For example, if the transmission is an uplink transmission, control information (including the preemption-coding indicator) may be included in an uplink control information (UCI) signal.

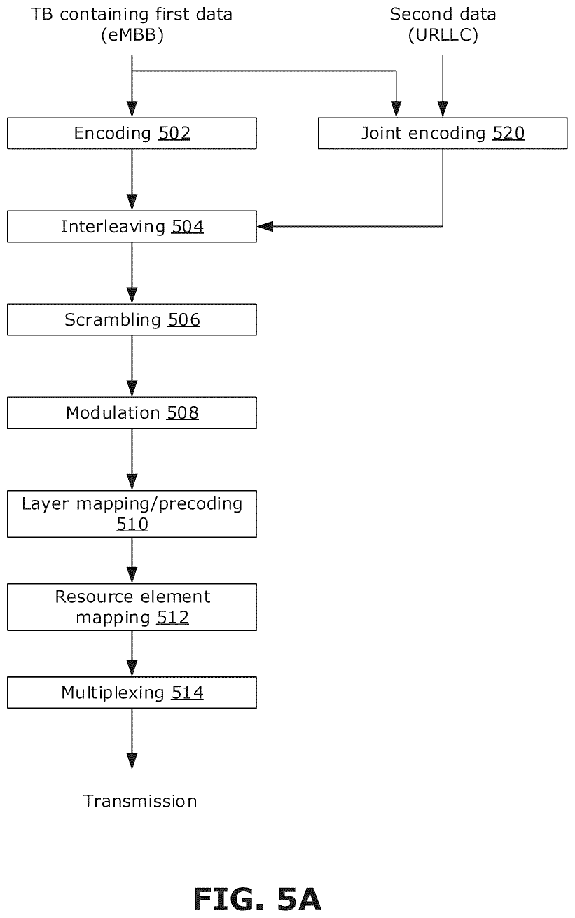

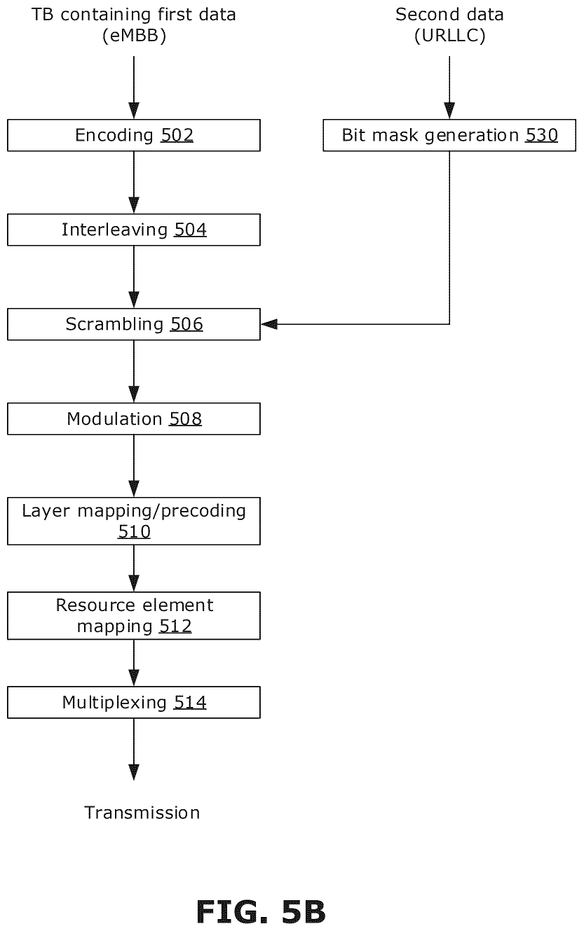

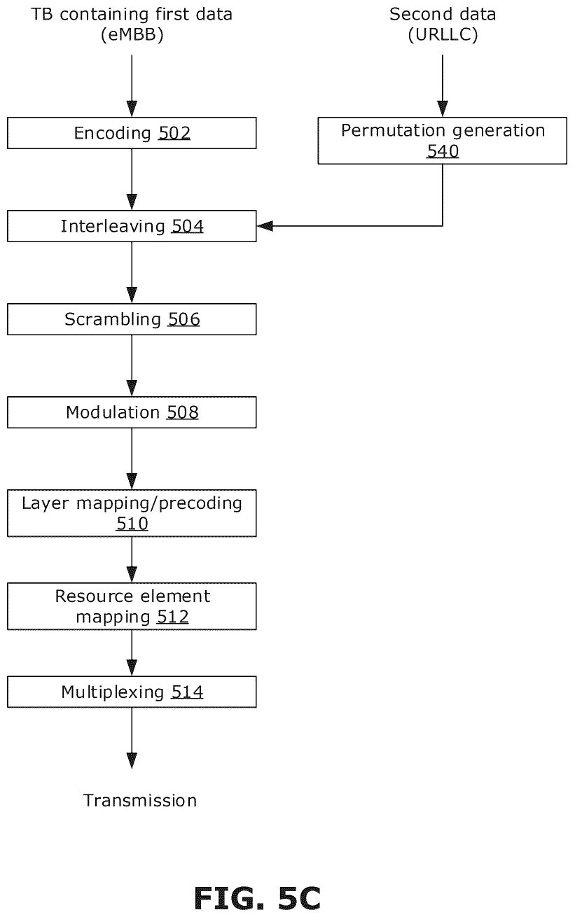

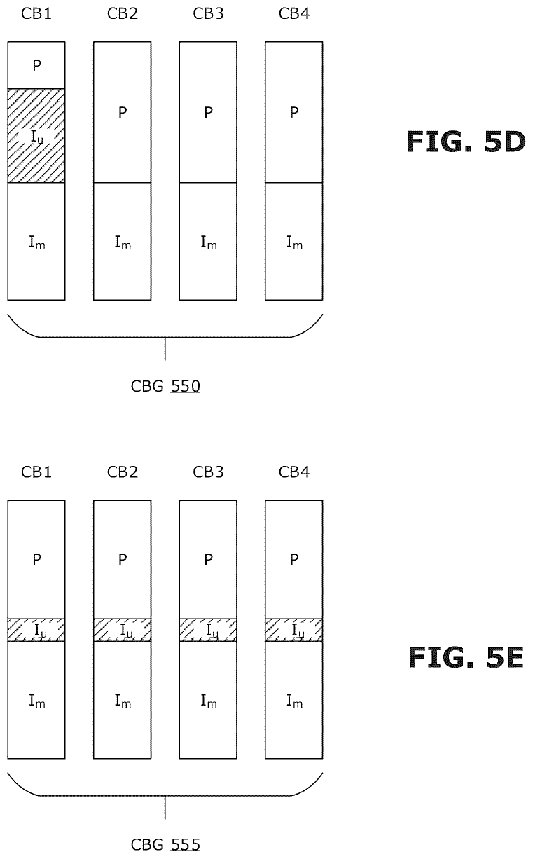

FIGS. 5A-5C illustrate some examples of how combined-data coding may be implemented at a transmitter node (e.g., a BS 170 or a UE 110). The example coding chains illustrated in FIGS. 5A-5C may be implemented using the processing unit 201 and communication interface 202 of an apparatus 200 that is the transmitter node, for example. A single transmitter node may be configurable to implement any of the example coding chains illustrated in FIGS. 5A-5C, or may implement only one or only two of the coding chains illustrated in FIGS. 5A-5C.

FIG. 5A illustrates an example in which combined-data coding is performed using joint encoding. Prior to the arrival of a set of second data (e.g., high priority or high urgency data, such as URLLC data), the transport block (TB) containing a set of first data (e.g., lower priority data, such as eMBB data) is processed by the coding chain including operations 502 to 514. The TB may be segmented into one or more CBs (not shown). Each CB is encoded at an encoding operation 502 (e.g., using low-density parity-check (LDPC) code), followed by an interleaving operation 504 (and possibly other operations such as rate matching). The resulting sequence of coded bits is processed by a scrambling operation 506, which may involve performing a bitwise XOR operation between the sequence of coded bits and a scrambling sequence. The scrambling operation 506 is followed by a modulation operation 508 that modulates the scrambled bit sequence into modulated symbols. The symbols are optionally mapped by a layer mapping/precoding operation 510, and then mapped to resource elements by a resource element mapping operation 512. Finally, the signals are multiplexed onto carrier frequencies by a multiplexing operation 514 (e.g., using orthogonal frequency-division multiplexing (OFDM)) and transmitted.

When the second data arrives, the transmitter node may identify the second data as being latency critical data that should be transmitted immediately (instead of waiting for resources to be scheduled). The arrival of the second data may interrupt the current processing of the first data (which may be in the process of being processed from a buffer). Instead of processing the waiting bits of the first data using the regular encoding operation 502, bits of the first data and bits of the second data are jointly encoded using a joint encoding operation 520. Joint encoding may be performed using any suitable encoding method that combines the bits of the first data and the bits of the second data, for example by linear combination among other possibilities. The jointly encoded bits are then processed by the interleaving operation 504 and the following operations 506 to 514 of the coding chain as described above. When the bits of the second data have all been jointly encoded, the remaining bits of the first data (which may still be waiting in the buffer) may be processed using the regular encoding operation 502 and the rest of the operations 504 to 514. The resulting combined-data-coded CB(s) is (are) then transmitted.

The coding chain of FIG. 5A, which uses joint encoding to embed the second data into the first data, may be suitable where the second data has a small to medium payload size (e.g., ˜10 bits to several bytes). To ensure the latency critical second data is received earlier, the jointly encoded bits may be mapped onto bit positions that are decoded earlier or that are higher priority positions.

FIG. 5B illustrates another example coding chain, in which combined-data coding is performed using a scrambling operation. Some components of the coding chain illustrated in FIG. 5B are similar to that of FIG. 5A, and the similar components need not be described again in detail.

Prior to the arrival of a set of second data (e.g., high priority or high urgency data, such as URLLC data), the transport block (TB) containing a set of first data (e.g., lower priority data, such as eMBB data) is processed by the coding chain including operations 502 to 514, as described above. When the second data arrives and is identified by the transmitter node as being latency critical data that should be transmitted immediately, the bits of the second data are first processed by a bit mask generation operation 530. The bit mask generation operation 530 uses the bits of the second data to generate a scrambling pattern in the form of a bit mask. For example, the bit pattern of the second data may be used in a function or formula to generate a binary sequence (e.g., a Gold sequence or any other suitable randomization sequence) that may then be used as a bit mask. In some examples, the bit mask may be generated simply by repeating the bits of the second data until a sufficient bit length is achieved. The bit mask (which may have the same bit length as a codeword generated from bits of the first data) is then used in the scrambling operation 506. In this way, the bits of the URLLC data are encoded in the scrambled bit sequence generated by the scrambling operation 506. The scrambled bit sequence is then processed by the following operations 508 to 514 as usual, then the resulting combined-data-coded CB(s) is (are) transmitted.

FIG. 5C illustrates another example coding chain, in which combined-data coding is performed using a permutation operation. Some components of the coding chain illustrated in FIG. 5C are similar to that of FIG. 5A, and the similar components need not be described again in detail.

Prior to the arrival of a set of second data (e.g., high priority or high urgency data, such as URLLC data), the transport block (TB) containing a set of first data (e.g., lower priority data, such as eMBB data) is processed by the coding chain including operations 502 to 514, as described above. When the second data arrives and is identified by the transmitter node as being latency critical data that should be transmitted immediately, the bits of the second data are first processed by a permutation generation operation 540. The permutation generation operation 540 uses the bits of the second data as a permutation sequence to determine how to permutate the bits of the first data in the interleaving operation 504 (it may be noted that this operation may also be referred to as a permutation operation instead of interleaving operation). For example, if a codeword generated from the bits of the first data is a cyclic code of length 8, there are 8 possible unique permutations such that the binary vector after applying the permutation is also a valid codeword (this is a property of cyclic codes). Then, each possible permutation may be associated with a respective 3-bit permutation sequence. For example, the permutation sequence 001 may be associated with a cyclic shift by one, and the permutation sequence 010 may be associated with a cyclic shift by two. Thus, if the bits of the second data are “010”, the permutation generation operation 540 determines that a cyclic shift by two should be performed at the interleaving operation. In this way, the bits of the URLLC data are encoded in the interleaved bit sequence generated by the interleaving operation 504. The interleaved bit sequence is then processed by the following operations 506 to 514 as usual, then the resulting combined-data-coded CB(s) is (are) transmitted.

Combined-data coding using scrambling or permutation (e.g., using the example coding chain of FIG. 5B or FIG. 5C) implicitly embeds the second set of data in the first set of data. Specifically, the second set of data (e.g., URLLC data) is implicitly embedded in the scrambling sequence or permutation sequence applied to the bits of the first set of data (e.g., eMBB data). Scrambling or permutation may be suitable in the case where the second set of data is of small payload size (e.g., fewer than or equal to 10 bits in size). The receiver node receives an indicator (e.g., via a control signal) indicating if scrambling or permutation was used for combined-data coding. At the decoder of the receiver node, blind decoding may be performed in which the decoder attempts to decode the combined-data coded CB(s) using all possible scrambling sequences or permutation sequences (depending on whether scrambling or permutation was used for combined-data coding). When the decoder finds one scrambling sequence or permutation sequence that successfully decodes the combined-data coded CB(s), the payload corresponding to the successful scrambling sequence or permutation sequence is determined to be the decoded second set of data (e.g., decoded URLLC bits). For example, the receiver node may use a predefined lookup table, predefined rule, or predefined function (e.g., as defined in a standard) that maps scrambling sequences or permutation sequences to bit sequences; thus, the predefined table, rule or function may be used to map the successful scrambling sequence or permutation sequence to a particular bit sequence that forms the decoded bits of the second set of data.

It should be noted that when combined-data coding is used, whether using joint coding, scrambling, or permutation, the length of the transmitted codeword may not be changed by the combined-data coding. This means that, in the case of joint coding, the code rate may be increased. As well, the size of the TB may be changed by the addition of the second set of data embedded in the combined-data-coded CB(s). Thus, a TB size calculation step may be required to update the size of the TB based on the payload size of the additional second set of data. The transmitter node may recalculate the TB size and provide information about the updated TB size in control information (e.g., in a DCI, UCI or other control signaling).

As noted above, combined-data coding will increase the code rate of a CB. FIGS. 5D and 5E illustrate examples of how the code rate of a CB may be increased by the additional bits of the second set of data.

In both the examples of FIGS. 5D and 5E, the incumbent first set of data is eMBB data and the second set of data is URLLC data. The URLLC information bits (denoted as Iᵤ) are added to CBs carrying incumbent eMBB information bits (denoted as Iₘ) as well as parity bits (denoted as P). In these simplified examples, there are four CBs (denoted CB1 to CB4) belonging to a CB group (CBG).

In the CBG 550 of FIG. 5D, the URLLC information bits Iᵤ are all added to CB1. The result is that the code rate of CB1 is significantly increased and the performance (e.g., block error rate (BLER)) of CB1 is significantly worsened. Meanwhile, the code rates and performance of CB2 to CB4 are unchanged. In another example CBG 555 of FIG. 5E, the URLLC information bits Iᵤ are distributed across all the CBs of the CBG 555. The URLLC information bits Iᵤ may be distributed evenly, approximately evenly (e.g., if the number of URLLC information bits Iᵤ is not evenly divisible by the number of CBs), or unevenly. Regardless of how the URLLC information bits Iᵤ are distributed across the CBs of the CBG 555, the result is that a plurality (or all) the CBs of the CGB 555 have a moderate or slight increase in code rate and a moderate or slight decrease in performance.

In some examples, when bits of the second set of data are added to CBs containing bits of the first set of data (e.g., for joint coding), it may be preferable for the added bits of the second set of data to be multiplexed across a plurality of CBs rather than being all multiplexed to only one CB, to avoid significant performance degradation of that one CB.

The disclosed example techniques for combined-data coding first and second sets of data belonging to different transmission types may be suitable in cases where both the first and second sets of data are intended for the same receiver node. This is because the receiver node needs to be able to decode both the first set of data and the second set of data from the combined-data-coded CB(s). For example, UL transmission of two different transmission types (e.g., eMBB data and URLLC data) from a UE 110 to a BS 170 may be intended for the same receiver node (i.e., the same BS 170). DL and SL transmissions of two different transmission types may be less frequently intended for the same receiver node.

Other preemption-coding schemes are disclosed herein, which may be suitable in cases where the first and second sets of data are intended for different receiver nodes, which may be a common scenario for DL and SL transmissions. For example, the first set of data (e.g., eMBB data) may be intended to be received by a first UE 110 and the second set of data (e.g., URLLC data or mMTC data) may be intended to be received by a second UE 110.

Example preemption-coding schemes using multi-level coding (MLC) are now described. MLC is a coding technique that has been described previously (e.g., see Imai et al. “A new multilevel coding method using error-correcting codes”, IEEE Transactions on Information Theory, 1977, incorporated herein by reference). However, MLC has not been adapted for multiplexing first and second sets of data belonging to different transmission types. The present disclosure describes preemption-coding schemes that adapts MLC to multiplex two sets of data belonging to different transmission types, where the two sets of data are intended for different recipients.

In preemption-coding using MLC, there are separate codewords generated for each set of data belonging to each respective transmission type (e.g., data bits from the eMBB transmission are encoded into one codeword, and data bits from the URLLC transmission are encoded into a separate codeword). The different code words are mapped to a common symbol on the constellation, so that a transmitted symbol carries bits belonging to different codewords of respective different transmissions.

Consider the example where there is a first set of data belonging to a first incumbent transmission type (e.g., an incumbent, lower priority transmission) and a second set of data belonging to a second preemptive transmission type (e.g., a newly arrived, higher priority transmission). Each set of data is intended for a respective different recipient (e.g., the first set of data is intended for a first receiver node and the second set of data is intended for a second receiver node). Preemption-coding using MLC may involve first encoding the payload data of each transmission type into one or more codewords. Then, a certain number of code bits is selected from the codeword(s) belonging to each transmission type, and the selected code bits are concatenated together into a bit vector. The code bits in the bit vector may be ordered such that the code bits selected from the codeword(s) belonging to the second (e.g., higher priority) transmission type (also referred to simply as the second code bits) are placed in the least significant bit (LSB) position(s) and the code bits selected from the codeword(s) belonging to the first (e.g., incumbent, lower priority) transmission type (also referred to simply as the first code bits) are placed in the most significant bit (MSB) position(s). The code bits of the second transmission type may be placed in the LSB position(s) because the LSB are demodulated earlier than the MSB and do not suffer from error propagation. The bit vector is then mapped into one symbol. Thus, the first and second code bits (carrying information corresponding to the first and second sets of data) are jointly mapped to one symbol. The symbol may then be transmitted by the transmitter node to the different intended receiver nodes. Each receiver node receives the transmitted symbol, demodulates the symbol and decodes the bits. Notably, because decoding typically starts from the LSB positions, the second receiver node (which is the intended recipient of the second set of data) may only need to decode the second code bits (which correspond to the second set of data and are in the LSB positions) without having to decode the first code bits. This may help to reduce latency where the second set of data belongs to a latency-sensitive transmission type (e.g., URLLC).

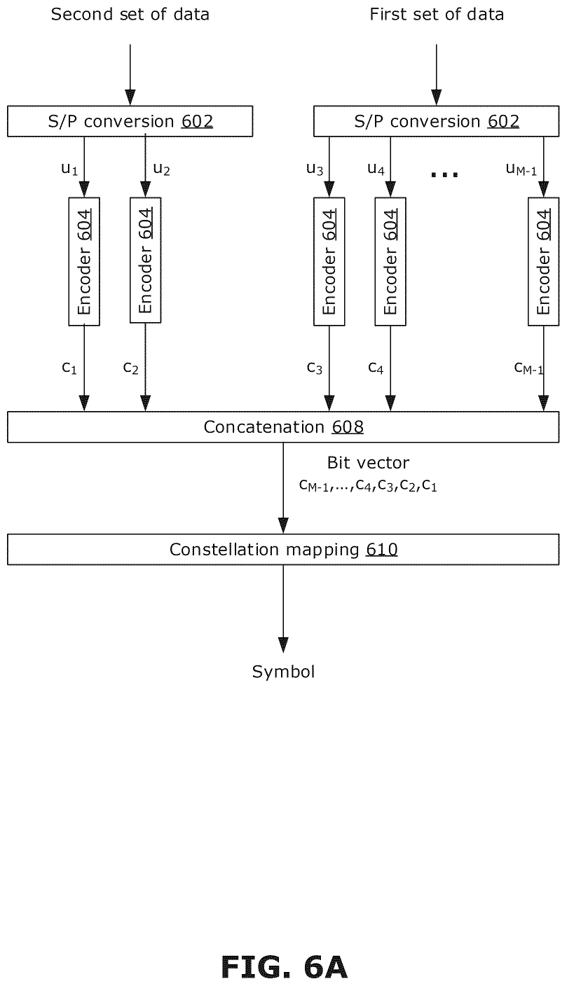

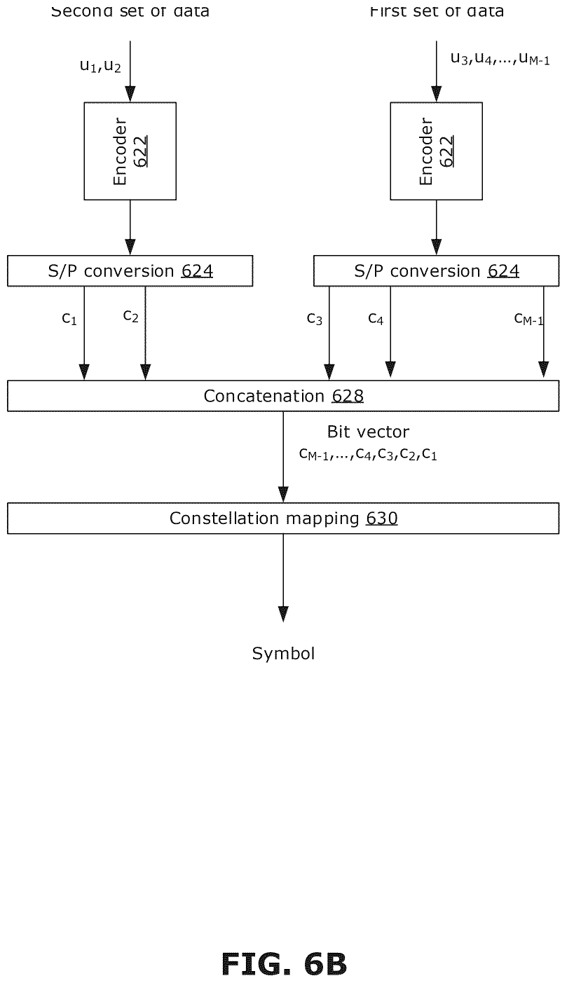

FIG. 6A is a schematic diagram illustrating an example of preemption-coding using MLC, which may be implemented at the transmitter node to jointly map code bits generated from first and second sets of data to a common MLC symbol.

In this example, a first set of data corresponds to a first incumbent transmission type (e.g., lower priority transmission, such as eMBB transmission) and a second set of data corresponds to a newly arrived second preemptive transmission type for a different service (e.g., high priority transmission, such as URLLC transmission). A serial-to-parallel (S/P) conversion operation 602 is performed on the payload bits of each set of data. The payload bits from the second set of data are divided into u₁ and u₂ information vectors (each information vector being one or more bits), and payload bits from the first set of data are divided into u₃, u₄, . . . . u_{M-1} information vectors. More generally, if the modulation order is m, then there are m levels (that is, the number of levels is equal to the modulation order), with m₁ levels allocated to carry information vectors from the first set of data and m₂ levels allocated to carry information vectors from the second set of data (and where m₁+m₂=m). Then, each information vector carried on each level is encoded by encoders 604 into a respective codeword. Thus, MLC is performed between the data bits of the first and second sets of data, as well as within the data bits of the first set of data.

Then one code bit is taken from each codeword, and the code bits are jointly mapped to a symbol. In general, m₁code bits are taken from the m₁ codewords generated from the second set of data, and m₂ code bits are taken from the m₂ codewords generated from the first set of data. In the example shown, one bit is taken from each codeword, such that the code bits c₁ and c₂ (referred to as the second code bits) are taken from the codewords generated from the second set of data (belonging to the second transmission type) and code bits c₃, c₄, . . . . c_{M-1} (referred to as the first code bits) are taken from the codewords generated from the first set of data (belonging to the first transmission type).

The first and second code bits are concatenated by a concatenation operation 608. The concatenation may be performed such that the high priority second code bits are placed in the LSB positions in the resulting bit vector c_{M-1}, . . . , c₄, c₃,c₂,c₁. The bit vector contains m bits, corresponding to the m-order modulation. The bit vector is mapped, using the constellation mapping operation 610, to a single symbol in the constellation (e.g., using 2^{m}-QAM modulation). An Ungerboeck set partitioning may be used for the constellation mapping. An advantage of using Ungerboeck set partitioning is that the Euclidean distance increases as more bits are decoded at the receiver node. However, other forms of partitioning may also be used.

FIG. 6B is a schematic diagram illustrating another example of preemption-coding using MLC, which may be implemented at the transmitter node to jointly map code bits generated from first and second sets of data to a common symbol.

Similar to the example of FIG. 6A, in FIG. 6B a first set of data corresponds to a first incumbent transmission type (e.g., lower priority transmission, such as eMBB transmission) and a second set of data corresponds to a newly arrived second preemptive transmission type for a different service (e.g., high priority transmission, such as URLLC transmission). Compared to the example of FIG. 6A, in the example of FIG. 6B the number of levels is fewer than the modulation order.

The payload bits of the second set of data are encoded by an encoder 622 into a single codeword, and the payload bits of the first set of data are encoded by another encoder 622 into another codeword. The codewords are each processed by S/P conversion 624 into respective code vectors from which second code bits c₁ and c₂ and first code bits c₃, c₄, . . . . c_{M-1} are taken. For example, if the S/P conversion 624 divides the codeword generated from the second data set into m₁ second code vectors and divides the codeword generated from the first data set into m₂ first code vectors, then m₁ code bits are taken from the m₁ code vectors generated from the second set of data, and m₂ code bits are taken from the m₂ code vectors generated from the first set of data.

Then, similar to the example of FIG. 6A, the first and second code bits are concatenated by a concatenation operation 628. The concatenation may be performed such that the higher priority second code bits are placed in the LSB positions in the resulting bit vector c_{M-1}, . . . ,c₄,c₃,c₂,c₁. The bit vector is mapped, using the constellation mapping operation 630, to a single symbol in the constellation. This example may correspond to a 2-level MLC, where MLC is performed between the first and second sets of data, and bit interleaved coded modulation (BICM) is performed within the first set of data and also within the second set of data.

In this example, because the number of levels used for MLC is lower than the order of modulation (e.g., an l-level MLC is performed for 2^{m}-QAM modulation, where l<m), mixed set partitioning can be used. For example, Ungerboeck set partitioning may be performed between consecutive levels, and Gray labeling may be performed within each level.

Compared to the example of FIG. 6A, in the example of FIG. 6B there are fewer levels. This may allow the receiver node to implement a simpler decoder (rather than a decoder designed to decode each level bit-by-bit).

Regardless of how MLC-based preemption-coding is performed, after the first and second sets of data have been jointly mapped to symbols, for example as illustrated in FIG. 6A or 6B, the transmitter node transmits the symbols to the first and second receiver nodes (which are respective intended recipients of the first and second sets of data). At each receiver node, the signals received over the transmission channel are decoded using a decoder. Each receiver node may implement one of several possible decoders, some examples of which are described below.

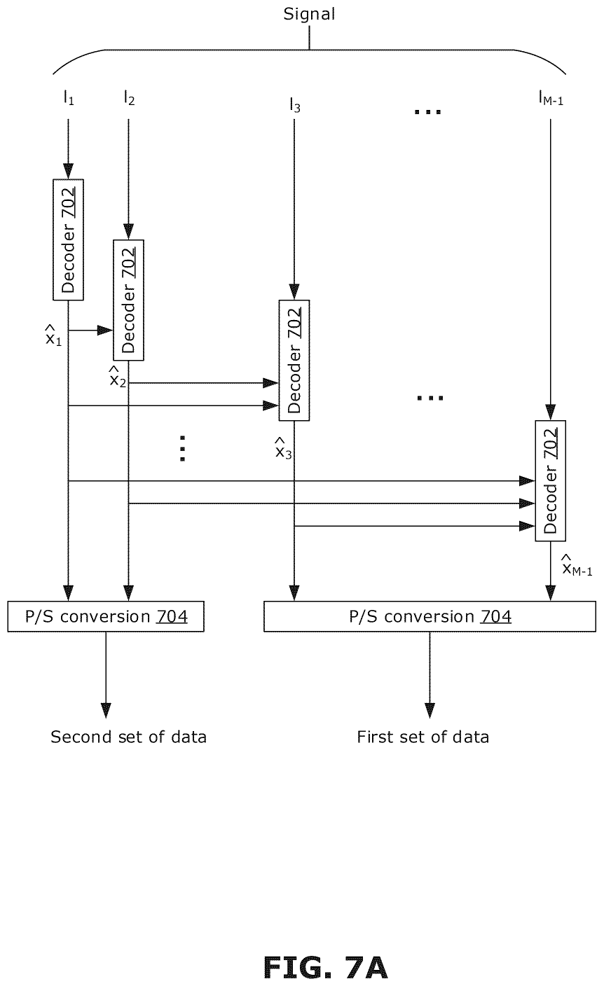

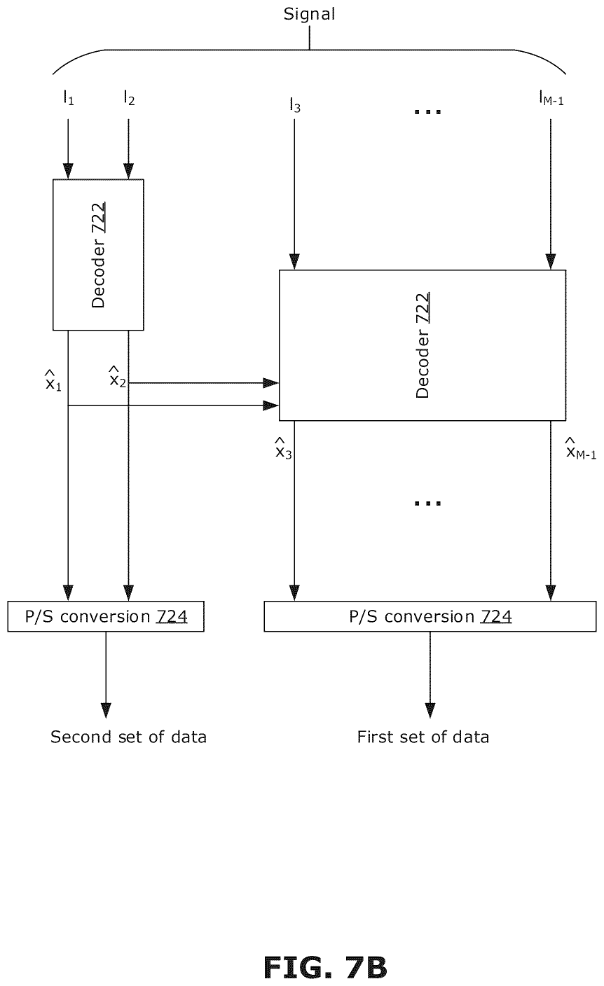

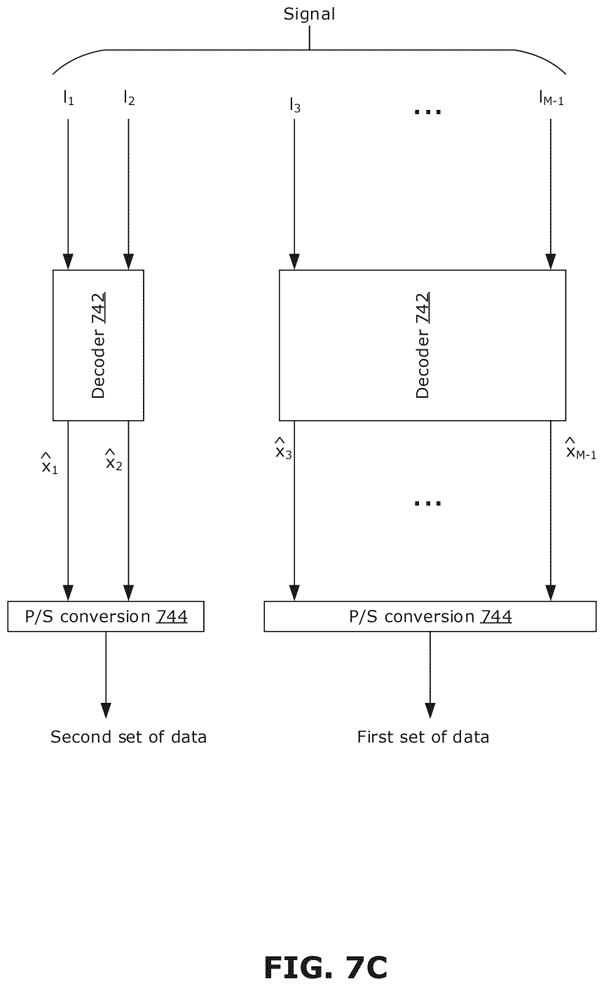

FIG. 7A is a schematic diagram illustrating an example of multi-stage decoding, which may be implemented at a receiver node when MLC-based preemption-coding is used at the transmitter node.

In this example, multi-stage decoding is used. The values of the received signal at each level are denoted l₁, l₂, l₃, . . . l_{M-1}. Each level is separately decoded by a respective decoder 702. The decoded bit decoded from each lower level is fed to the higher level decoders 702 to assist in the decoding. For example, the decoded bit \hat{x}₁ that is decoded from the level l₁ is fed to the next-level decoder 702 to assist in decoding the level l₂, and so forth. The decoded bits belonging to each respective set of data are processed by a parallel-to-serial (P/S) conversion 704 and outputted. The receiver node may know, from control information sent by the transmitter node, which levels correspond to which set of data and thus can separate the two sets of data accordingly. In this example, the decoded bits \hat{x}₁ and \hat{x}₂ from levels l₁ and l₂ are known to belong to the second set of data (belonging to the second transmission type, which may be a higher priority transmission such as URLLC), and the decoded bits \hat{x}₃ to \hat{x}_{M-1} from levels l₃ to l_{M-1}, are known to belong to the first set of data (belonging to the first incumbent transmission type, which may be a lower priority transmission such as eMBB).

It should be noted that the receiver node may be the intended recipient of only a particular one of the first or second sets of data. Thus, only the decoded bits belonging to the particular set of data that is relevant to the receiver node may be processed by the P/S conversion 704 and outputted. If the receiver node is the intended recipient of the second set of data, then the decoding may stop after the bits corresponding to the second set of data have been decoded (e.g., the remaining levels l₃ to l_{M-1}, may not need to be decoded). This may be useful to help reduce unnecessary processing at the receiver node. If the receiver node is the intended recipient of the first set of data, then it may be necessary to first decode the bits corresponding to the second set of data before decoding the bits corresponding to the first set of data (the decoded bits corresponding to the second set of data may then be discarded).

FIG. 7B is a schematic diagram illustrating an example of hybrid decoding, which may be implemented at a receiver node when MLC-based preemption-coding is used at the transmitter node.

Compared with the multi-stage decoding illustrated in FIG. 7A, the hybrid decoding shown in FIG. 7B may have sub-optimal performance (i.e., does not fully exploit the multi-level gain) but may be less complicated to implement at the receiver node.

In the example of FIG. 7B, all values at the levels corresponding to the second set of data (i.e., levels l₁ and l₂) are decoded by a single decoder 722. The decoded bits î₁ and \hat{x}₂ corresponding to the second set of data are used to assist in decoding the bits of the first set of data, which are all decoded by another decoder 722. Then, similarly to the example of FIG. 7A, the decoded bits belonging to each respective set of data are processed by a respective P/S conversion 724 and outputted. If the receiver node is the intended recipient of only the second set of data, then only the bits on levels l₁ and l₂ may need to be decoded. If the receiver node is the intended recipient of only the first set of data, then all the bits may be decoded and the bits corresponding to the second set of data may be discarded.

FIG. 7C is a schematic diagram illustrating an example of independent decoding, which may be implemented at a receiver node when MLC-based preemption-coding is used at the transmitter node.

Compared with the multi-stage decoding illustrated in FIG. 7A and the hybrid decoding shown in FIG. 7B, the independent decoding shown in FIG. 7C may have worse performance but may be more simple to implement at the receiver node.

In the example of FIG. 7C, all levels are modulated and decoded in parallel. In particular, a single decoder 742 decodes the levels corresponding to the second set of data and another decoder 742 decodes the levels corresponding to the first set of data. However, the decoded bits of the second set of data are not used to assist in decoding the bits of the first set of data. The decoded bits outputted by each decoder 742 are processed by a respective P/S conversion 744 and outputted. If the receiver node is the intended recipient of only the second set of data, then only the bits on levels l₁, and l₂ may need to be decoded. If the receiver node is the intended recipient of only the first set of data, then all the bits may be decoded and the bits corresponding to the second set of data may be discarded.

Preemption-coding using MLC may be suitable in cases where a high signal-to-noise ratio (SNR) modulation scheme is used, such as 16 QAM (where QAM stands for quadrature amplitude modulation), 32 QAM or 64 QAM. Other preemption-coding schemes using masked repetition coding (MRC) may be suitable in cases where a lower SNR modulation scheme is used, such as 4 QAM or quadrature phase shift keying (QPSK). Examples of preemption-coding using MRC are now described.

In MRC-based preemption-coding, a codeword generated from a higher priority second set of data (that is of a second preemptive transmission type) is masked onto part of the repeated symbols generated from a lower priority first set of data (that is of a first, incumbent transmission type). It may be noted that when the SNR is low (e.g., for an eMBB receiver node), such repetition is commonly performed to ensure reliable communication. The masking may be performed using modulo-2 addition (i.e., XOR) in the binary domain. MRC-based preemption-different coding may be used in scenarios where the first and second sets of data are intended for recipients, although this is not intended to be limiting.

Briefly, preemption-coding using MRC involves first identifying two or more copies (also referred to as repetitions) of a first codeword (or symbol) generated from the first set of data of the first incumbent transmission type. Then, a second codeword generated from the second set of data of the second preemptive transmission type is masked onto one or some (but not all) copies of the first codeword. The masked bits are then re-modulated into new symbol(s) to replace corresponding symbol(s) of the first transmission type.

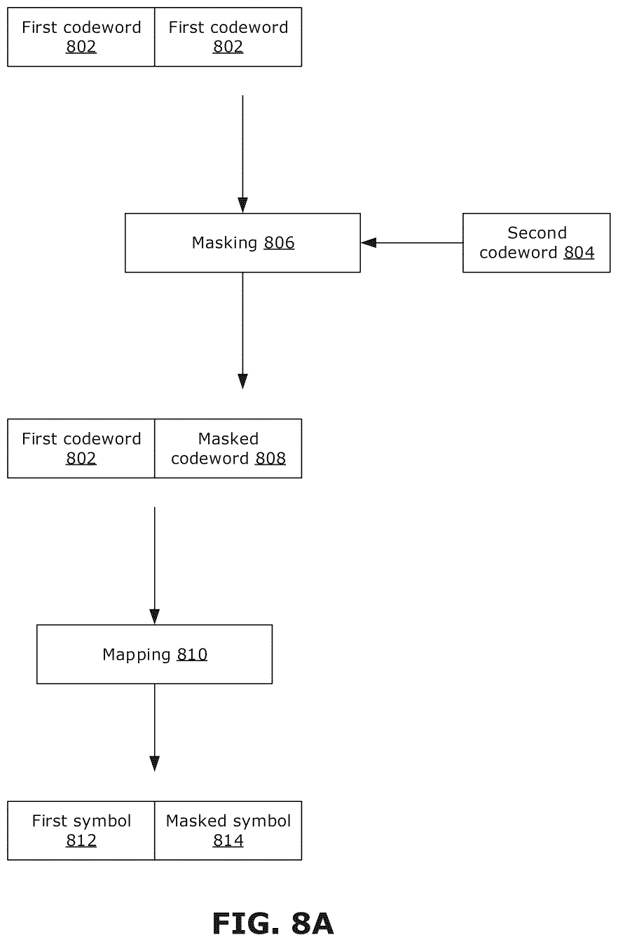

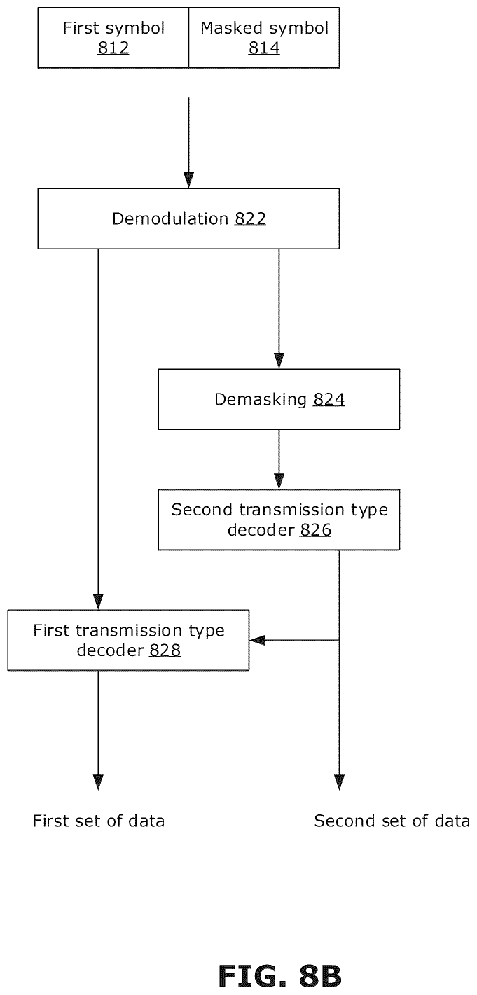

FIG. 8A is a schematic diagram illustrating an example of MRC-based preemption-coding, which may be implemented by the transmitter node.

In this example, the first set of data belonging to a first, incumbent transmission type may be eMBB data and the second set of data belonging to the second preemptive transmission type may be URLLC data, however this is not intended to be limiting. As shown, there may be two copies of a first codeword 802 generated from the first set of data. A second codeword 804, generated from the second set of data is masked onto one copy of the first codeword 802, using a masking operation 806, resulting in a masked codeword 808 that replaces one copy of the first codeword 802. The remaining (unmasked) copy of the first codeword 802 and the masked codeword 808 are then further mapped to a first symbol 812 and a masked symbol 814, respectively, and transmitted by the transmitter node. Thus, the masked symbol 814, which contains information from both the first set of data as well as the preemptive second set of data, replaces one instance of the first symbol 812 but not all instances of the first symbol 812 are replaced.

FIG. 8B is a schematic diagram illustrating an example of demasking and decoding that may be implemented at the receiver node. The receiver node may be the intended recipient of the first set of data, the second set of data, or both.

The first symbol 812 and the masked symbols 814 are first demodulated by a demodulation operation 822. The log-likelihood ratio (LLR) of the second codeword (which has been masked onto a copy of the first codeword) can be recovered by a demasking operation 824, using a demasking function (also referred to as an f-function). The demasking function may be as follows:

l=sgn(l₁,l₂)min(l₁,l₂)
where l₁ is the LLR of a bit of the first codeword and l₂ is the LLR of a bit of the masked codeword, l is the LLR of a bit of the recovered second codeword, and sgn denotes the sign function (a function that extracts the sign of a real number). Decoding of the second codeword, to recover the second set of data, may be performed by a second transmission type decoder 826 (e.g., a URLLC decoder, in the case where the second transmission type is URLLC transmission) after all LLRs of the bits of the second codeword have been recovered from the demasking operation 824. The decoded second codeword may be fed to a first transmission type decoder 828 (e.g., an eMBB decoder, in the case where the first transmission type is eMBB transmission), together with the demodulated symbols, to recover the first set of data.

If the receiver node is the intended recipient of the second set of data only, the receiver node does not need to decode the first set of data (and does not need to use the first transmission type decoder 828). If the receiver node is the intended recipient of the first set of data only, the receiver node may only need to decode the unmasked first codeword using the first transmission type decoder 828 without having to perform the demasking 824 operation and without having to decode the second codeword. Alternatively, even if the receiver node is not the intended recipient of the second set of data, the receiver node may still perform the demasking operation 824 and decode the bits of the second codeword to assist in decoding the first codeword (and thus benefit from repetition gain).

In the above discussion, different techniques for performing preemption-coding have been described. It should be understood that the transmitter node may be capable of performing any of the preemption-coding techniques described above, and may be configured to use a selected preemption-coding technique depending on the intended receiver node(s) and/or the available SNR. For example, when data for both the first, incumbent transmission type and the second, preemptive transmission type are intended for the same receiver node, the transmitter node may use the combined-data coding preemption-coding scheme. In another example, when data for the first, incumbent transmission type and data for the second, preemptive transmission type are intended for respective different receiver nodes, the transmitter node may use the MLC preemption-coding scheme when the SNR is high, or may use the MRC preemption-coding scheme with the SNR is low.

Regardless of how preemption-coding is performed by the transmitter node, the transmitter node may, in some examples, map the preemption-coded symbols to non-consecutive physical resource blocks (PRBs).

Reference is again made to FIG. 3. Conventionally, symbols belonging one CB (e.g., all the symbols belonging to the URLLC packet 304), which preempt the incumbent eMBB packet 302, are mapped to consecutive PRBs. This means that one or more eMBB CBs are significantly punctured and thus would very likely be unsuccessfully decoded. This drawback may be mitigated by the non-consecutive mapping disclosed herein.

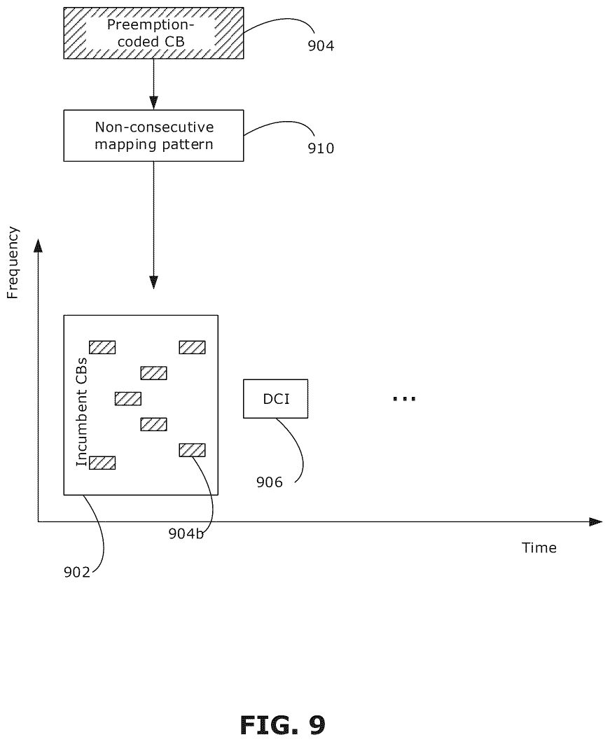

FIG. 9 is a schematic diagram illustrating an example of non-consecutive mapping that may be performed by a transmitter node, as disclosed herein.

A preemption-coded CB 904 may be generated by the transmitter node using any suitable preemption-coding scheme as described above, such as the MLC preemption-coding scheme. The preemption-coded CB 904 includes a plurality of preemption-coded symbols 904b. The transmitter node applies a non-consecutive mapping pattern 910 to map the symbols 904b of the preemption-coded CB 904 to different, non-consecutive resource elements (REs) currently being used to transmit incumbent CBs 902. The non-consecutive mapping pattern 910 may be a sparse pattern, such that each incumbent CB 902 is only slighted interfered (compared to the conventional case shown in FIG. 3). The non-consecutive mapping pattern 910 may map the preemption-coded symbols 904b to equally-spaced REs or to pseudo-randomly selected REs, for example. For example, the non-consecutive mapping pattern 910 may define a mapping that maps the preemption-coded symbols 904b to REs at a regular defined interval (e.g., if the interval is denoted as p, then the preemption-coded symbols 904b may be mapped to the REs at position 1, p+1, 2p+1, etc.). In another example, the non-consecutive mapping pattern 910 may be specified using a pseudo-random sequence where the indices in the pseudo-random sequence indicate the REs to which the preemption-coded symbols 904b are to be mapped.

The non-consecutive mapping pattern 910 may be predefined (e.g., in a standard) and may be indicated to the receiver node in the subsequently-transmitted DCI 906 (transmitted in the next timeslot), to enable the receiver node to identify and decode the preemption-coded symbols 904b. It should be noted that, while a DCI 906 is shown in FIG. 9, any suitable control signaling may be used. For example, if the transmission is an uplink transmission, control information (including indication of the non-consecutive mapping pattern 910) may be included in a UCI.

The non-consecutive mapping pattern 910 may be used by the transmitter node to map symbols of a preemptive transmission type, even if preemption-coding as disclosed herein is not used. For example, the transmitter node may use the non-consecutive mapping pattern 910, as disclosed herein, to map symbols of the URLLC packet 304 of FIG. 3 to non-consecutive REs, to help mitigate the interference to the incumbent eMBB packet 302, and may indicate the non-consecutive mapping pattern 910 in the DCI 306 (or other control signaling).

To support the preemption-coding scheme disclosed herein, suitable control signaling may be used to enable the receiver node to appropriately decode the data of the first or second transmission type. For example, referring to FIGS. 4 and 9, the DCI 406, 906 that is transmitted in the timeslot following transmission of the preemption-coded CB 404 or the non-consecutively mapped preemption-coded symbols 904b, may be used to communicate preemption-coding information to the receiver node. In general, the preemption-coding information may be communicated in any suitable control signal, which may be a DCI signal, a UCI signal or other control signaling.

The preemption-coding information that may be included in the control signaling may include the number of preempted incumbent CBs and the position of the preempted incumbent CBs; the type of preemption-coding used (e.g., none, combined-data coding (in particular, whether joint coding, scrambling or permutation is used), MLC, or MRC); and/or the updated TB size and MCS index (e.g., code length, information length) for each preempted CB. The code length and code rate used in the coding of the incumbent transmission type as well as the code length and code rate used in the coding of the preemptive transmission type may be included in the control signaling.

Further, depending on the preemption-coding scheme used by the transmitter node, the control signaling may include additional information. If combined-data coding using joint coding was used, the code type used for both the incumbent and preemptive transmission types may be indicated in the control signaling. If combined-data coding using scrambling was used, the set of scrambling sequences use (e.g., Gold sequences or M-sequences) may be indicated in the control signaling. If combined-data coding using permutation was used, a set of permutation sequences (e.g., an automorphism group) may be indicated in the control signaling. If MLC preemption-coding was used, the layers selected for each transmission type, the constellation mapping (e.g., mixed set partitioning), and the rate allocation between the two transmission types may be indicated in the control signaling. If MRC preemption-coding was used, the rate allocation between the two transmission types, and which of the incumbent block is masked may be indicated in the control signaling.

In examples where a non-consecutive mapping pattern was used to map preemption- coded symbols to non-consecutive REs, the non-consecutive mapping pattern may be indicated in the control signaling. In some examples, the non-consecutive mapping pattern or a set of available non-consecutive mapping patterns may be predefined (e.g., defined in a standard) and the control signaling may include an indicator (e.g., in a numeric field) indicating which predefined non-consecutive mapping pattern was used.

This information may enable the receiver node to identify which portions of the received transmission contain preemption-coded data. Instead of flushing the soft LLRs corresponding to this portion of the transmission and thus losing any soft information contained in the soft LLRs (which is the case in conventional preemptive transmissions), the receiver node may use the soft decoding information to assist in decoding of the first or second transmission type, as discussed above. For example, while the signal quality of the bits of the first incumbent transmission type may be low (due to the interference caused by the bits of the second preemptive transmission type), there is still soft information (e.g., likelihood information) about the bits of the first transmission type contained in the soft LLRs that may be used to help decode the bits of the first transmission type.

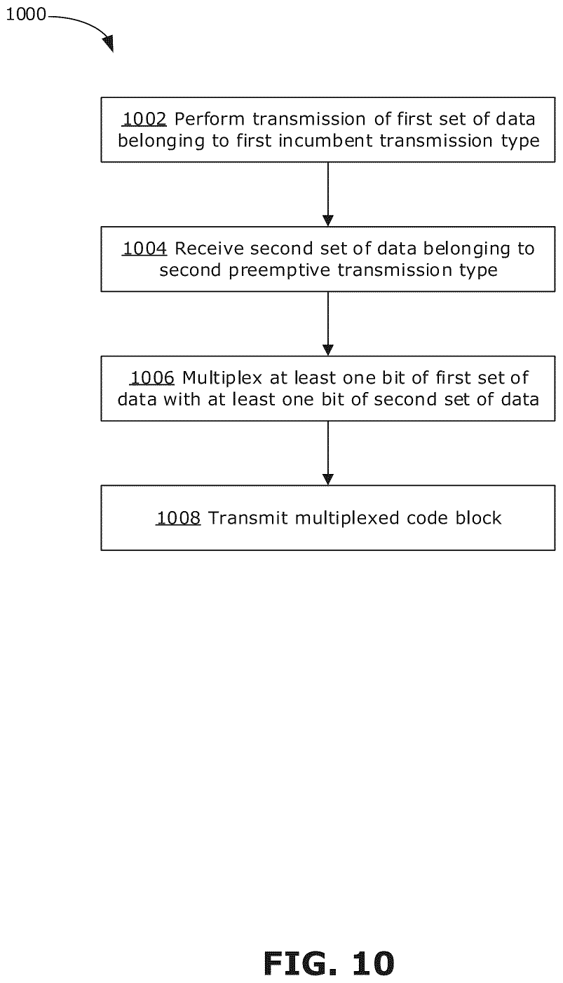

FIG. 10 is a flowchart illustrating an example method 1000 for using preemption-coding to multiplex a first set of data belonging to a first, incumbent transmission type (e.g., eMBB data) with a second set of data belonging to a second, preemptive transmission type (e.g., URLLC data). The method 1000 may be performed by a transmitter node, which may be a BS 170, a UE 110, or other transmitting device in a wireless system such as the wireless communication system 100 of FIG. 1. For example, the method 1000 may be performed by a processing unit executing non-transitory computer-readable instructions stored in a memory.

At 1002, the transmitter node performs a scheduled transmission of a first set of data belonging to a first incumbent transmission type (e.g., eMBB transmission) to an intended recipient.

At 1004, during or before the scheduled transmission of the first incumbent transmission type, a second set of data belonging to a second preemptive transmission type (e.g., URLLC transmission) is obtained or received. The second transmission type may be any transmission type that is considered to be higher priority than the first transmission type (e.g., having stricter low-latency requirements than the first transmission type) and thus requires transmission without waiting for the first transmission type to complete transmission. For example, the second set of data may be a set of URLLC data, received by the transmitter node from another node or internally generated by the transmitter node, that should be transmitted at the earliest opportunity. The second set of data may be intended for the same recipient as the first set of data, or may be intended for a different recipient.

At 1006, at least one bit of the first set of data is multiplexed with at least one bit of the second set of data. Various techniques may be used to perform this multiplexing, including combined-data coding (e.g., joint coding, scrambling, permutation), MLC or MRC, as disclosed herein. Regardless of how multiplexing is performed, the result is a multiplexed code block containing at least one multiplexed symbol containing information from both the first and second sets of data.

At 1008, the transmitter node outputs the multiplexed code block, for example by transmitting the multiplexed code block. The multiplexed code block may replace an incumbent code block containing information from only the first set of data. The multiplexed code block may be transmitted to the intended recipient of both the first set of data and the second set of data (if both sets of data have the same intended recipient), or to the intended recipient of the first set of data and the other intended recipient of the second set of data (if the two sets of data have two different intended recipients).

Although not shown in FIG. 10, transmission of the multiplexed code block may be followed by transmission of control signaling (e.g., in the next timeslot) with information to enable the intended recipient(s) to properly decode and recover the first and second sets of data (e.g., the control information as described above).

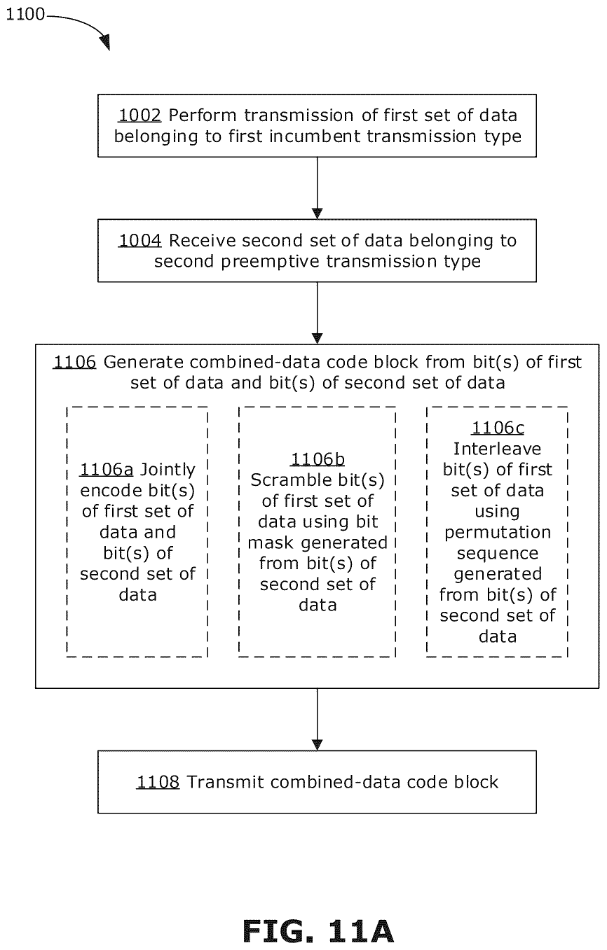

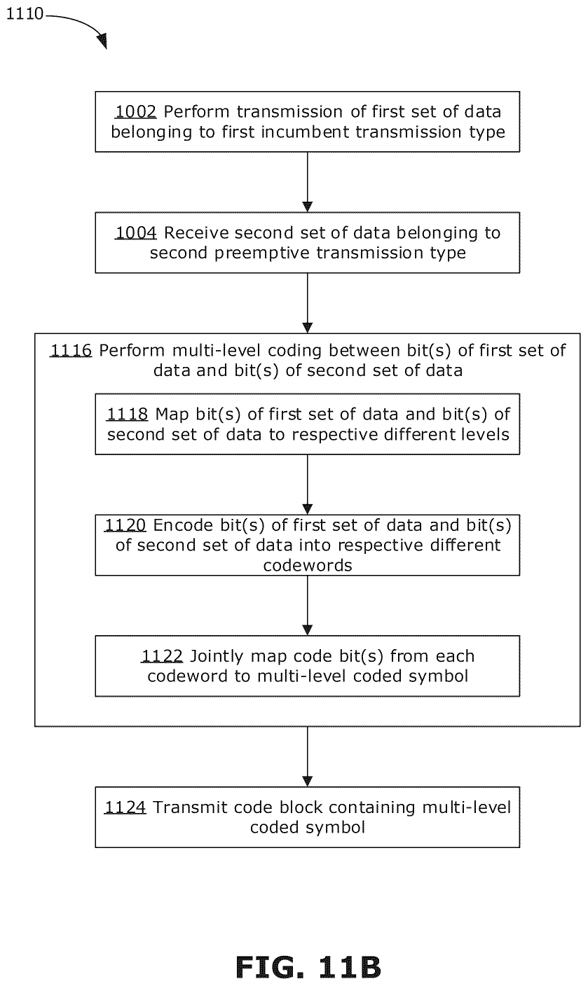

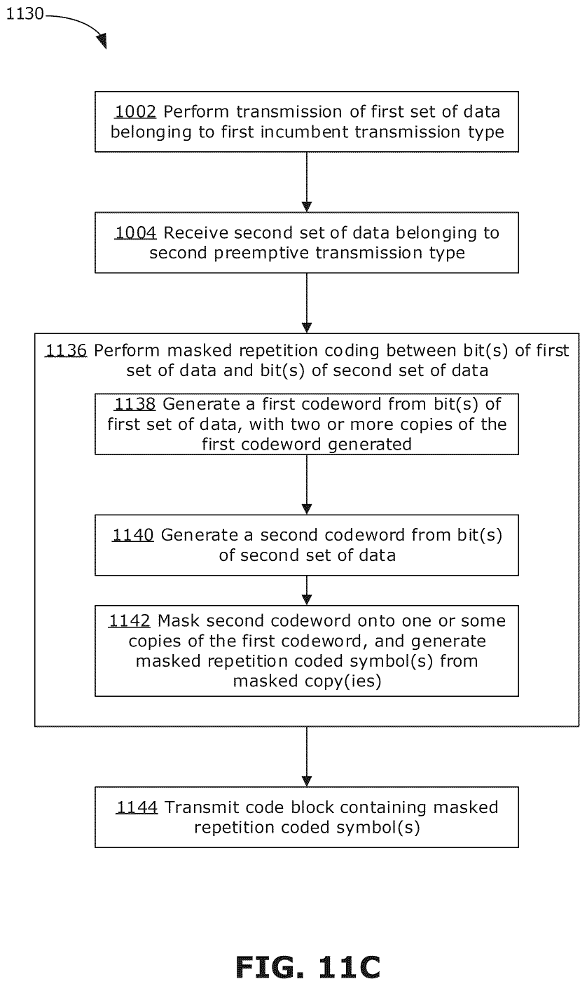

FIGS. 11A-11C are flowcharts illustrating examples of how the method 1000 may be carried out using various preemption-coding techniques as disclosed herein.

FIG. 11A is a flowchart illustrating an example method 1100, which is an example implementation of the method 1000 of FIG. 10, in which the multiplexing between the data of the first incumbent transmission type and the data of the second preemptive transmission type is performed using combined-data coding.

The method 1100 includes steps 1002 and 1004, described above with respective to FIG. 10.

At 1106 (which is an example implementation of step 1006), a combined-data code block (which may be an example implementation of the multiplexed code block) is generated from at least one bit of the first set of data and at least one bit of the second set of data. The combined-data code block may be generated by performing step 1106a, 1106b or 1106c, for example.

At 1106a, at least one bit of the first set of data and at least one bit of the second set of data are jointly encoded (e.g., as illustrated in FIG. 5A) and the jointly encoded codeword is further processed by the coding chain.

At 1106b, at least one bit of the second set of data is used to generate a bit mask. At least one bit of the first set of data is scrambled by the bit mask (e.g., as illustrated in FIG. 5B), and further processed by the coding chain.

At 1106c, at least one bit of the second set of data is used to generate a permutation sequence. At least one bit of the first set of data is interleaved using the permutation sequence (e.g., as illustrated in FIG. 5C), and further processed by the coding chain.

Regardless of how the combined-data code block is generated, at 1108 (which is an example implementation of step 1008), the transmitter node outputs the combined-data code block, for example by transmitting the combined-data code block. The combined-data code block is transmitted in place of an incumbent code block containing only information from the first transmission type.

FIG. 11B is a flowchart illustrating an example method 1110, which is an example implementation of the method 1000 of FIG. 10, in which the multiplexing between the data of the first incumbent transmission type and the data of the second preemptive transmission type is performed using MLC.

The method 1110 includes steps 1002 and 1004, described above with respective to FIG. 10.

At 1116 (which is an example implementation of step 1006), MLC is performed between one or more bits of the first set of data and one or more bits of the second set of data. MLC may be performed using steps 1118-1122, for example.

At 1118, one or more bits of the first set of data and one or more bits of the second set of data are mapped to different levels. It should be noted that the bits of the first and second sets of data are mapped to different levels such that there is no level that carried bits from both the first and second sets of data. In some examples, the number of levels may be equal to the modulation order (e.g., as shown in FIG. 6A); in other examples, the number of levels may be fewer than the modulation order (e.g., as shown in FIG. 6B).

At 1120, the bit(s) carried on each level is encoded by respective encoders into respective codewords. Since each level carries only bit(s) from the first set of data or only bit(s) from the second set of data, this means that the bit(s) of the first set of data and the bit(s) of the second set of data are encoded into different codewords.

At 1122, one or more code bits are selected from each codeword generated at step 1120, and the code bits are jointly mapped to a multi-level coded symbol. This may involve, for example, concatenating code bit(s) selected from codewords generated from the first set of data with code bit(s) selected from codewords generated from the second set of data, to arrive at a bit vector containing bits from different codewords (e.g., as illustrated in FIG. 6A or 6B). The bit vector is then mapped to a symbol. Because the symbol contains code bits corresponding to different levels, the symbol is referred to as a multi-level coded symbol.

At 1124 (which is an example implementation of step 1008), the transmitter node outputs the code block containing the multi-level coded symbol, for example by transmitting the code block containing the multi-level coded symbol. The MLC code block is transmitted in place of an incumbent code block containing only information from the first transmission type.

FIG. 11C is a flowchart illustrating an example method 1130, which is an example implementation of the method 1000 of FIG. 10, in which the multiplexing between the data of the first incumbent transmission type and the data of the second preemptive transmission type is performed using MRC.

The method 1110 includes steps 1002 and 1004, described above with respective to FIG. 10.

At 1136 (which is an example implementation of step 1006), MRC is performed between one or more bits of the first set of data and one or more bits of the second set of data. MLC may be performed using steps 1138-1142, for example.

At 1138, a first codeword is generated from one or more bits of the first set of data. In particular, two or more copies of the first codeword is generated.

At 1140, a second codeword is generated from one or more bits of the second set of data.

At 1142, the second codeword is masked onto one or some (but not all) copies of the first codeword. The result is at least one (unmasked) copy of the first codeword and one or more copies of the masked codeword (e.g., as illustrated in FIG. 8A). Both the unmasked and masked codewords are modulated into symbols. In particular, one or more masked repetition coded symbols are generated from the one or more masked codewords.

At 1144 (which is an example implementation of step 1008), the transmitter node outputs the code block containing the masked repetition coded symbol(s), for example by transmitting the code block containing the masked repetition coded symbol(s). The MRC code block is transmitted in place of an incumbent code block containing only information from the first transmission type.

In various examples, the present disclose has described methods and system in which an incumbent transmission type (e.g., eMBB) is multiplexed with a preemptive transmission type (e.g., URLLC) in a multiplexed transmission. Using the example preemption-coding techniques disclosed herein, rather than having to discard incumbent data that has been preempted (which may be considered equivalent to puncturing the incumbent transmission), data of the preemptive transmission type is multiplexed with and transmitted together with data of the incumbent transmission type. This may help to avoid a high likelihood of failure to decode the preempted data of the incumbent transmission and may also avoid the need to use outer erasure codes. At the same time, the data of the preemptive transmission type can be transmitted at the earliest opportunity, thus enabling low-latency transmission for latency-critical data.

The present disclosure has described different preemption-coding techniques that may be used to multiplex data of an incumbent transmission type with data of a preemptive transmission type. The different preemption-coding techniques disclosed herein may be suitable for different transmission scenarios, including scenarios where the same receiver node is the intended recipient of both transmission types, where different receiver nodes are the intended recipient of the different transmission types, and for high-SNR or low-SNR transmissions.

Examples of the present disclosure may be implemented in current and next-generation mobile and wireless networks (e.g., 5G networks, 5G+ networks, 6G networks, WiFi networks, non-terrestrial networks, distributed networks or self-organized networks), including cloud and edge computing services, and sensing services. The wireless system in which examples of the present disclosure may be implemented may include cellular networks, ad-hoc networks, and others, and may involve BS-UE communications, UE-UE (or device-to-device) communications, among others.

Examples of the present disclosure may be useful in any application involving mixed transmission types (e.g., mixed URLLC and eMBB traffic, mixed mMTC and eMBB traffic, mixed IoT and eMBB traffic, etc.). For example, human-centric communications (e.g., in which wearable devices may communicate with wireless networks and smartphones), autonomous or semi-autonomous industrial applications (e.g., in which URLLC traffic may be used to control autonomous robots in a factory, together with eMBB or other large packet traffic), or distributed sensing systems (e.g., in which sensors transmit small mMTC packets that overlap with eMBB or other large packet traffic) may benefit from examples disclosed herein.

Although the present disclosure has described BSs and UEs as examples of transmitter nodes and receiver nodes, it should be understood that other wireless communication devices may perform the functions of transmitter node and/or receiver node as disclosed herein. For example, the present disclosure may be implemented using BSs, UEs, autonomous devices, robots, drones, wireless communication-capable vehicles, satellites, smart appliances, etc.

Although the present disclosure describes methods and processes with steps in a certain order, one or more steps of the methods and processes may be omitted or altered as appropriate. One or more steps may take place in an order other than that in which they are described, as appropriate.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein. The machine-executable instructions may be in the form of code sequences, configuration information, or other data, which, when executed, cause a machine (e.g., a processor or other processing device) to perform steps in a method according to examples of the present disclosure.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

1. A method at a transmitter node, comprising:
during or before a scheduled transmission of a first set of data belonging to a first transmission type to an intended receiver node, obtaining a second set of data belonging to a second transmission type to be transmitted to the intended receiver node or a different intended receiver node from the intended receiver node;
multiplexing at least one bit of the first set of data and at least one bit of the second set of data to generate at least one multiplexed code block containing information from both the first set of data and the second set of data; and
outputting the at least one multiplexed code block.

2. The method of claim 1, wherein the first set of data and the second set of data are to be transmitted to the intended receiver node, and wherein the multiplexing the at least one bit of the first set of data and the at least one bit of the second set of data comprises one of:
jointly encoding the at least one bit of the first set of data and the at least one bit of the second set of data into a jointly encoded codeword;
scrambling the at least one bit of the first set of data using a bit mask generated from the at least one bit of the second set of data; or
interleaving the at least one bit of the first set of data using a permutation sequence generated from the at least one bit of the second set of data.

3. The method of claim 2, wherein one or more bits of the second set of data are multiplexed in each of a plurality of multiplexed code blocks.

4. The method of claim 1, wherein the second set of data is to be transmitted to the different intended receiver node,
wherein the multiplexing the at least one bit of the first set of data and the at least one bit of the second set of data comprises:
performing multi-level coding between the at least one bit of the first set of data and the at least one bit of the second set of data to obtain a multi-level coded symbol, and
wherein the outputting the at least one multiplexed code block comprises:
transmitting the multiplexed code block containing the multi-level coded symbol to the intended receiver node and the different intended receiver node.

5. The method of claim 1, wherein the second set of data is to be transmitted to the different intended receiver node,
wherein the multiplexing the at least one bit of the first set of data and the at least one bit of the second set of data comprises:
performing masked repetition coding between the at least one bit of the first set of data and the at least one bit of the second set of data to obtain a masked repetition coded symbol, and
wherein the outputting the at least one multiplexed code block comprises:
transmitting the multiplexed code block containing the masked repetition coded symbol to the intended receiver node and the different intended receiver node.

6. The method of claim 1, further comprising:
after all bits of the second set of data have been transmitted, resuming the scheduled transmission of the first set of data.

7. The method of claim 1, further comprising:
transmitting control information to at least one intended receiver node, the control information including information for decoding the at least one multiplexed code block.

8. The method of claim 7, wherein an updated transport block size is computed for the multiplexed code block and the updated transport block size is included in the transmitted control information.

9. An apparatus comprising:
at least one processor; and
a memory storing instructions which, when executed by the at least one processor, cause the apparatus to perform:
during or before a scheduled transmission of a first set of data belonging to a first transmission type to an intended receiver node, obtaining a second set of data belonging to a second transmission type to be transmitted to the intended receiver node or a different intended receiver node from the intended receiver node;
multiplexing at least one bit of the first set of data and at least one bit of the second set of data to generate at least one multiplexed code block containing information from both the first set of data and the second set of data; and
outputting the at least one multiplexed code block.

10. The apparatus of claim 9, wherein the first set of data and the second set of data are to be transmitted to the intended receiver node, and wherein the multiplexing the at least one bit of the first set of data and the at least one bit of the second set of data comprises one of:
jointly encoding the at least one bit of the first set of data and the at least one bit of the second set of data into a jointly encoded codeword;
scrambling the at least one bit of the first set of data using a bit mask generated from the at least one bit of the second set of data; or
interleaving the at least one bit of the first set of data using a permutation sequence generated from the at least one bit of the second set of data.

11. The apparatus of claim 10, wherein one or more bits of the second set of data are multiplexed in each of a plurality of multiplexed code blocks.

12. The apparatus of claim 9, wherein the second set of data is to be transmitted to the different intended receiver node,
wherein the multiplexing the at least one bit of the first set of data and the at least one bit of the second set of data comprises:
performing multi-level coding between the at least one bit of the first set of data and the at least one bit of the second set of data to obtain a multi-level coded symbol, and
wherein the outputting the at least one multiplexed code block comprises:
transmitting the multiplexed code block containing the multi-level coded symbol to the intended receiver node and the different intended receiver node.

13. The apparatus of claim 9, wherein the second set of data is to be transmitted to the different intended receiver node,
wherein the multiplexing the at least one bit of the first set of data and the at least one bit of the second set of data comprises:
performing masked repetition coding between the at least one bit of the first set of data and the at least one bit of the second set of data to obtain a masked repetition coded symbol, and
wherein the outputting the at least one multiplexed code block comprises:
transmitting the multiplexed code block containing the masked repetition coded symbol to the intended receiver node and the different intended receiver node.

14. The apparatus of claim 9, wherein the instructions further cause the apparatus to perform:
after all bits of the second set of data have been transmitted, resuming the scheduled transmission of the first set of data.

15. The apparatus of claim 9, wherein the instructions further cause the apparatus to perform:
transmitting control information to at least one intended receiver node, the control information including information for decoding the at least one multiplexed code block.

16. The apparatus of claim 15, wherein an updated transport block size is computed for the multiplexed code block and the updated transport block size is included in the transmitted control information.

17. A method at a receiver node, comprising:
receiving at least one multiplexed code block generated from multiplexing at least one bit of a first set of data and at least one bit of a second set of data to contain information from both the first set of data and the second set of data, the first set of data belonging to a first transmission type and scheduled for the receiver node, and the second set of data belonging to a second transmission type and intended for the receiver node or a different receiver node than the receiver node; and
decoding at least the information from the first set of data.

18. An apparatus comprising:
at least one processor; and
a memory storing instructions which, when executed by the at least one processor, cause the apparatus to perform:
receiving at least one multiplexed code block generated from multiplexing at least one bit of a first set of data and at least one bit of a second set of data to contain information from both the first set of data and the second set of data, the first set of data belonging to a first transmission type and scheduled for a receiver node comprising the apparatus or a different receiver node from the receiver node, and the second set of data belonging to a second transmission type and intended for the same receiver node; and
decoding at least the information from the second set of data.

19. A method at a receiver node, comprising:
receiving at least one multiplexed code block generated from multiplexing at least one bit of a first set of data and at least one bit of a second set of data to contain information from both the first set of data and the second set of data, the first set of data belonging to a first transmission type and scheduled for the receiver node or a different receiver node from the receiver node, and the second set of data belonging to a second transmission type and intended for the receiver node; and
decoding at least the information from the second set of data.

20. An apparatus comprising:
at least one processor; and
a memory storing instructions which, when executed by the at least one processor, cause the apparatus to perform:
receiving at least one multiplexed code block generated from multiplexing at least one bit of a first set of data and at least one bit of a second set of data to contain information from both the first set of data and the second set of data, the first set of data belonging to a first transmission type and scheduled for the receiver node comprising the apparatus or a different receiver node from the receiver node, and the second set of data belonging to a second transmission type and intended for the receiver node; and
decoding at least the information from the second set of data.
